(19) United States
(12) Patent Application Publication
(10) Pub. No.: US 2010/0247810 A1
(43) Pub. Date: Sep. 30, 2010

(54) FLEXIBLE TRANSPARENT CONDUCTIVE FILM AND FLEXIBLE FUNCTIONAL ELEMENT USING THE SAME

(76) Inventors: Masaya Yukinobu, Chiba (JP); Yuki Murayama, Chiba (JP); Hirotoshi Izaki, Tokyo (JP)

Correspondence Address: KRATZ, QUINTOS & HANSON, LLP, 1420 K Street, N.W., 4th Floor, WASHINGTON, DC, 20005, US

(21) Appl. No.: 12/739,849

(22) PCT Filed: Oct. 29, 2008
(86) PCT No.: PCT/JP2008/069648

§ 371 Date: Apr. 26, 2010

(30) Foreign Application Priority Data
Oct. 31, 2007 (JP) 2007-283645
Jul. 1, 2008 (JP) 2008-172326

(51) Int. Cl. B32B 9/00; B32B 7/02; C09K 19/52; H05B 33/14

(52) U.S. Cl. 428/1.4; 428/688; 428/702; 428/697; 428/337; 428/690; 428/537.5

(57) ABSTRACT

A flexible transparent conductive film includes a base film 1, and a first transparent conductive layer 2a formed by a vapor deposition method and a second transparent conductive layer 3a formed by a coating method, these layers being laminated in the described order or in order reversed thereto on the base film 1, wherein the first transparent conductive layer 2a mainly includes a conductive oxide, the second transparent conductive layer 3a mainly includes conductive oxide fine particles and a binder matrix. The first transparent conductive layer 2a and the second transparent conductive layer 3a adhere to each other so as to restrain generation of a crack in the first transparent conductive layer 2a, or to restrain deterioration in conductivity when the crack has been generated. This configuration enables to provide the flexible transparent conductive film comparable to a conventional sputtered ITO film in terms of transparency, conductivity, and stability of conductivity, and having excellent flexibility, and to provide a flexible functional element using the flexible transparent conductive film.

### TECHNICAL FIELD

The present invention relates to a transparent conductive film having a transparent conductive layer formed on a base film, and in particular, relates to a transparent conductive film used for a flexible functional element such as a liquid crystal display element, an organic electroluminescence element, an electronic paper element, a solar cell or a touch panel.

### BACKGROUND ART

Recently, technical progress toward light, thin and small is accelerating in a field of electronic devices such as various display devices including a liquid crystal display element, and a mobile phone. Along with this progress, intensive researches have been done to replace a conventional glass substrate by a plastic film. The plastic film is characterized by its lightness and excellent flexibility. Accordingly, a transparent conductive film having a base film made of a thin plastic film of several micrometers thick, and a transparent conductive layer formed thereon can provide a flexible functional element having characteristics of extremely light and flexible, if such transparent conductive film can be applied to, for example, a liquid crystal display element, an organic electroluminescence element (hereinafter abbreviated to an “organic EL element”), a dispersion-type electroluminescence element (hereinafter abbreviated to an “dispersion-type EL element”), an electronic paper element, a solar cell, and a touch panel.

The transparent conductive film used in the flexible functional element has a structure, as illustrated in FIG. 1, in which a transparent conductive layer 2 is formed on a base film 1 by a vapor deposition method. It is widely known that the transparent conductive film in general has the transparent conductive layer 2 of indium tin oxide (hereinafter abbreviated as “ITO”) formed on the base film 1 by a physical vapor deposition method such as sputtering or ion plating. It is to be noted that the transparent conductive layer of this type is hereinafter abbreviated as “sputtered ITO layer”, and transparent conductive film of this type is hereinafter abbreviated as “sputtered ITO film”.

The above-described sputtered ITO film, for example, has a base film made of a transparent plastic film such as polyethylene terephthalate (PET) or polyethylene naphthalate (PEN), and has an inorganic single layer of ITO of about 20 to 50 nm thick which is formed on the base film by a physical vapor deposition method. With this configuration, a transparent conductive layer having a low-resistance of about 100 to 300 Ω/square (pronounced as “ohm per square”) in surface resistivity can be obtained.

However, the sputtered ITO layer is formed to have a thin film shape of an inorganic component and is extremely brittle, and therefore it has a problem in that micro cracks (cracks) are easily generated therein. Specifically, when a sputtered ITO film having a base film of less than 50 μm thick, for example 25 μm thick, is used in a flexible functional element as described above, the base film is too flexible so that the sputtered ITO layer is easily cracked during the time when the sputtered ITO film by itself is handled or after the sputtered ITO film is incorporated into the flexible functional element. Thus, the conductivity of the transparent conductive layer may be remarkably damaged. Accordingly, the sputtered ITO film has not been put to practical use in a flexible functional element which requires high flexibility.

For this reason, instead of the above-described vapor deposition method such as sputtering, a coating method is proposed as disclosed in for example Patent Documents 1 to 6 cited below in which a transparent conductive layer having relatively flexible feature is formed on a plastic base film. Specifically, a coating liquid for forming a transparent conductive layer, which mainly includes conductive oxide fine particles and a binder, is applied onto a base film and dried. Thereafter, compression (rolling) treatment with rolls is applied thereto, and then the binder component is cured.

According to this method, a transparent conductive film as illustrated in FIG. 2 can be obtained which has a base film 1 and a transparent conductive layer 3 formed thereon by the coating method. This method makes it possible to increase the filling density of the conductive fine particles in the transparent conductive layer by the rolling treatment with the rolls, and therefore this method has an advantage to greatly improve the electric (conductive) property and optical property of the transparent conductive layer.

Patent Document 7 cited below discloses a dispersion-type electroluminescence element having at least a transparent coating layer, a transparent conductive layer, a fluorescent layer, a dielectric layer, and a rear electrode layer, which are successively formed on a surface of a base film. The transparent conductive layer in this element is formed by applying a coating liquid for forming the transparent conductive layer, which mainly includes conductive oxide particles and a binder, on the surface of the transparent coating layer so as to form a coating film, and then compression treatment is applied to the coating film.

Patent Document 1: Japanese Patent Application Laid-Open (JP-A) No. 4-237909

Patent Document 2: JP-A No. 5-036314

Patent Document 3: JP-A No. 2001-321717

Patent Document 4: JP-A No. 2002-36411

Patent Document 5: JP-A No. 2002-42558

Patent Document 6: WO 2007/039969

Patent Document 7: JP-A No. 2006-202739

### DISCLOSURE OF THE INVENTION

### Problems to be Solved by the Invention

Even though the conventional coating method described above for forming the transparent conductive layer greatly improves the flexibility, the resultant transparent conductive layer is poor in transparency and conductivity (transparent and conductive property) as compared with the sputtered ITO film. This is because the transparent conductive layer formed by the conventional coating method has such a structure that conductive oxide particles are jointed to each other by a point contact, and electric current flows through the contact point. For example, a sputtered ITO film has the specific resistance of about 2 to 6×10⁻⁴ Ω·cm. In contrast, a transparent conductive film with a coating film has the specific resistance of 2 to 6×10⁻² Ω·cm, which is higher than the above specific resistance by two orders of magnitude, even though the coating film is made from ITO fine particles that have been densely packed by the compression treatment. Furthermore, transparent conductive layer formed by the coating method has a problem that the layer is susceptible to several factors such as deterioration with the passage of time or change caused by the atmospheric condition, so that stability of conductivity is poor.

As described above, there is no transparent conductive film available having transparency and stability of conductivity which are comparable to those of the sputtered ITO film, and having a transparent conductive layer excellent in flexibility. Therefore, it has been intensely desired to improve these properties of the transparent conductive film, which is used as a transparent electrode on the above-described flexible functional element, such as a liquid crystal display element, an organic EL element, a dispersion-type EL element, an electronic paper element, a solar cell or a touch panel.

The present invention has been made in view of the above situation. It is an objective of the present invention to provide a flexible transparent conductive film having transparency, conductivity, and stability of conductivity which are comparable to those of a conventional sputtered ITO film, and having excellent flexibility so as to be used in, in particular, a flexible functional element such as a liquid crystal display element, an organic EL element, a dispersion-type EL element, an electronic paper element, a solar cell or a touch panel.

### Means for Solving the Problems

In order to attain the objective, the flexible transparent conductive film according to the present invention includes a base film, and a first transparent conductive layer formed by a physical or chemical vapor deposition method and a second transparent conductive layer formed by a coating method. These layers are laminated in the described order or in order reversed to the described order on the base film. Further, the first transparent conductive layer mainly includes a conductive oxide, and the second transparent conductive layer mainly includes conductive oxide fine particles and a binder matrix. The first transparent conductive layer and the second transparent conductive layer adhere to each other so as to restrain generation of a crack in the first transparent conductive layer, or to restrain deterioration in conductivity when the crack has been generated.

In the flexible transparent conductive film of the present invention, the second transparent conductive layer may be subjected to compression treatment.

In the flexible transparent conductive film of the present invention, the physical or chemical vapor deposition method may be sputtering, ion plating, vacuum evaporation, thermal CVD, photo CVD, Cat-CVD, or MOCVD.

In the flexible transparent conductive film of the present invention, the conductive oxide and the conductive oxide fine particles mainly include one or more components selected from the group consisting of indium oxide, tin oxide, and zinc oxide.

In the flexible transparent conductive film of the present invention, it is preferable that the oxide included in the conductive oxide and the conductive oxide fine particles is indium tin oxide.

In the flexible transparent conductive film of the present invention, it is preferable that the binder matrix is crosslinked, and has organic-solvent resistance.

In the flexible transparent conductive film of the present invention, it is preferable that the compression treatment is performed by rolling treatment by using rolls.

In the flexible transparent conductive film of the present invention, it is preferable that the base film has a thickness of 3 to 50 μm, and a supporting film is adhere onto a surface of the base film, the supporting film has a capability of being peeled off at an interface between the supporting film and the base film.

The flexible functional element according to the present invention has a structure in which a functional element is formed on the flexible transparent conductive film of the present invention, the functional element being a liquid crystal display element, an organic electroluminescence element, an inorganic dispersion-type electroluminescence element, an electric paper element, a solar cell or a touch panel. Further, when the base film having a supporting film adhered thereto is used in fabrication of the flexible functional element, the resultant flexible functional element has no supporting film which has been peeled off at the interface between the supporting film and the base film.

### Effects of the Invention

According to the present invention, it is possible to obtain a flexible transparent conductive film having transparency, conductivity, and stability of conductivity which are comparable to those of a conventional sputtered ITO film, and having excellent flexibility. Furthermore, use of this flexible transparent conductive film makes it possible to produce, at low cost, various flexible functional elements, such as a liquid crystal display element, an organic EL element, a dispersion-type EL element, an electronic paper element, a solar cell and a touch panel. Thus, the present invention is industrially useful.

### BRIEF DESCRIPTION OF THE DRAWINGS

FIG. 1 is a schematic sectional view illustrating a structure of a conventional transparent conductive film.

FIG. 2 is a schematic sectional view illustrating another structure of the conventional transparent conductive film.

FIG. 3 is a schematic sectional view illustrating a structure of a flexible transparent conductive film according to the present invention.

FIG. 4 is a schematic sectional view illustrating another structure of the flexible transparent conductive film according to the present invention.

FIG. 5 is a schematic sectional view illustrating a situation of the generation of cracks when a conventional transparent conductive film is bent.

FIG. 6 is a schematic sectional view illustrating a situation of the generation of cracks when a flexible transparent conductive film according to the present invention is bent.

FIG. 7 is a schematic view illustrating a test sample used in flexibility evaluations (2) of conventional transparent conductive films and flexible transparent conductive films according to the present invention (a view seen from the above thereof and from a side thereof).

FIG. 8 is a schematic sectional view illustrating a situation of the generation of cracks when the conventional transparent conductive film is completely twice-folded.

FIG. 9 is a schematic sectional view illustrating a situation of the generation of cracks when the flexible transparent conductive film according to the present invention is completely twice-folded.

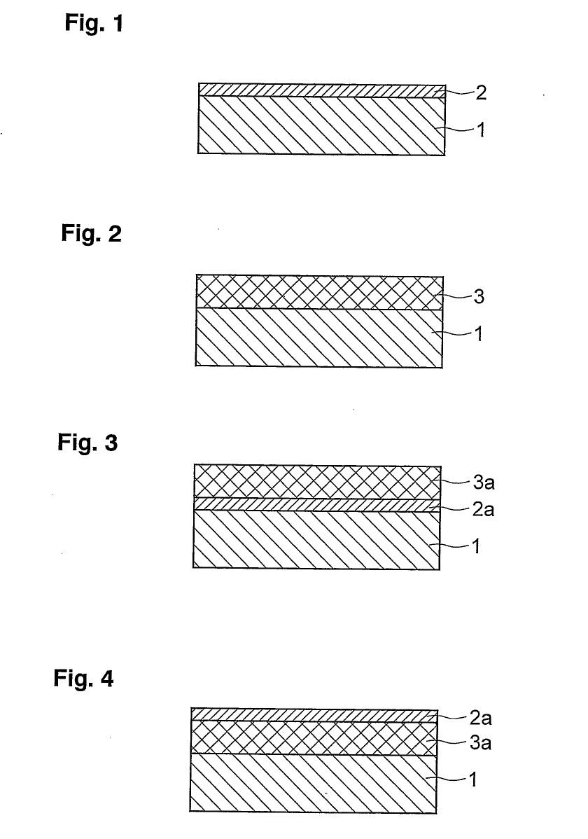

### EXPLANATION OF REFERENCE NUMERALS

1 Base film

2 Transparent conductive layer formed by a vapor deposition method

2a First transparent conductive layer

3 Transparent conductive layer formed by a coating method

3a Second transparent conductive layer

4 Cracks

5 Flexible transparent conductive film from which a supporting film is peeled off

5a Transparent conductive layer surface

6 Parallel electrodes formed by use of a silver conductive paste

7 Fold line

### BEST MODE FOR CARRYING OUT THE INVENTION

The flexible transparent conductive film of the present invention has a base film, and a first transparent conductive layer formed by a physical or chemical vapor deposition method and a second transparent conductive layer formed by a coating method. These layers are laminated in the described order or in order reversed thereto on the base film. The first transparent conductive layer mainly includes a conductive oxide, whereas the second transparent conductive layer mainly includes conductive oxide fine particles and a binder matrix. Furthermore, the first transparent conductive layer and the second transparent conductive layer adhere to each other so as to restrain generation of a crack in the first transparent conductive layer, or to restrain deterioration in conductivity when the crack has been generated.

On this flexible transparent conductive film, a functional element, that is, a liquid crystal display element, an organic EL element, an inorganic dispersion-type EL element, an electronic paper element, a solar cell or a touch panel is formed so as to provide a flexible functional element.

It is preferable as usual that the thickness of the base film used in the flexible transparent conductive film of the present invention is 3 μm or more (for example, 3 to 188 μm), more preferably from 6 to 125 μm, even more preferably from 6 to 50 μm. As the base film becomes thicker, the rigidity thereof generally becomes higher so that the flexible functional element loses its flexibility. On the other hand, as the base film becomes thinner, the flexible functional element gains more flexibility, but the handling of the film becomes more difficult during the production process, which may reduce productivity.

In particular, the base film having the thickness smaller than 3 μm is not preferable. This is because general purpose films distributed in the market become unavailable, and the handling of the base film itself becomes very difficult so that a lining process by the use of a supporting film described later becomes cumbersome. Moreover, the strength of the base film itself becomes lowered so that the transparent conductive layer or other components included in the flexible functional element may be damaged.

The material for the base film is not particularly limited as long as the material is transparent or translucent and the transparent conductive layer can be formed thereon. Accordingly, various plastics may be used for the base film. Specific examples of such plastics include polyethylene terephthalate (PET), polyethylene naphthalate (PEN), nylon, polyethersulfone (PES), polycarbonate (PC), polyethylene (PE), polypropylene (PP), urethane, and fluorine-contained resin, and so on. Among them, a PET film is preferable because it is inexpensive and excellent in strength, and has both transparency and flexibility.

The base film may be reinforced with an inorganic and/or organic (plastic) fiber (examples thereof including needle-form, rodlike, and whisker fine particles) or flake-form fine particles (examples thereof including plate-form particles). These kinds of base films reinforced with the fiber or flake-form fine particles can have a better strength even though the film is formed relatively thinner.

One surface of the base film, on which none of the first and second transparent conductive layers is formed, may be covered with a hard coating, antiglare coating, antireflection (low reflection) coating, gas barrier coating or the like. This surface is exposed to the outside and finally serves as the outermost surface of a flexible functional element of the present invention, because a functional element is formed on the first or second transparent conductive layer of the flexible transparent conductive film. Accordingly, application of the hard coating to the surface to be exposed improves the scratch resistance, which makes it possible to effectively prevent the flexible functional element from deterioration in display performance.

As for application of the antiglare coating or antireflection coating to the surface to be exposed, this coating suppresses the reflection of external light on the outermost surface of the flexible functional element, so that the display performance can be further improved. Whereas application of the gas barrier coating such as oxygen barrier or water vapor barrier to the surface to be exposed makes it possible to effectively prevent the flexible functional element from the deterioration in function, in the case where the element is susceptible to deterioration by oxygen or water vapor.

When the thickness of the base film is as small as 3 to 50 μm (in particular, 3 to 25 μm), it is preferable to line (reinforce) the base film by a supporting film in consideration of the handleability and the productivity of the flexible transparent conductive film during the production process. It is desirable that the supporting film, which may be also referred to as a lining film, has a weak adhesive layer on a surface adhered to the base film, and further the weak adhesive layer has a capability to be peeled off after adhered to the base film. When the supporting film is made of material that has by itself weak adhesive property, although not common, provision of the weak adhesive layer is not required, because the supporting film itself can additionally act as the weak adhesive layer.

It is preferable that the supporting film has a thickness of 50 μm or more, more preferably 75 μm or more, even more preferably 100 μm or more. This is because the supporting film having a thickness less than 50 μm is poor in film rigidity, which may cause a handling problem during a production process of the various flexible functional elements. Furthermore, it may cause a curling problem of the base film, and may also cause a problem associated with a production process of the functional element layer such as a problem associated with the lamination printing for a fluorescent layer or the like in producing a dispersion-type EL element. On the other hand, it is preferable that the supporting film has a thickness of 200 μm or less. This is because the supporting film having the thickness more than 200 μm makes the film hard and heavy so that the supporting film is not easily handled, and moreover, it is unfavorable from a viewpoint of production cost.

The material for the supporting film is not particularly limited, and thus various types of plastics may be used. Examples of such plastics include polycarbonate (PC), polyethylene terephthalate (PET), polyethylene naphthalate (PEN), nylon, polyethersulfone (PES), polyethylene (PE), polypropylene (PP), urethane, fluorine-contained resin, polyimide (PI), or the like. Among them, a PET film is preferable from viewpoints of low production cost, excellence in strength as well as flexibility. The supporting film should preferably be transparent, even though this feature is not directly relate to the requirement of the transparency for the flexible functional elements, because the flexible functional element may have a product quality test of brightness, external appearance, display performance, or the like at the end of the production phase, where the flexible functional element is examined or viewed through the supporting film. For this reason also, the PET film is preferable.

The supporting film, in a state attached to the base film, is subject to processing conditions for producing the flexible transparent conductive film and the flexible functional element, and is finally peeled off from the base film. Accordingly, the weak adhesive layer described above preferably has an appropriate peelability. The material for the weak adhesive layer may be an acrylic or silicone type. Of these types, the silicone-type is preferable for the weak adhesive layer from a viewpoint of better heat resistance.

It is preferable that the weak adhesive layer has the peel strength (i.e., force necessary to peel off per unit length in a peeled-off section) in a range of 1 to 40 g/cm, more preferably 2 to 20 g/cm, even more preferably 2 to 10 g/cm, which is determined by a 180° peel strength test (tensile speed is 300 mm/min) when the weak adhesive layer is peeled off from the base film. The peel strength less than 1 g/cm is not preferable, because the supporting film purposely attached to the base film is easily peeled off during the production process of the flexible transparent conductive film or the flexible functional element. On the other hand, the peel strength more than 40 g/cm is not preferable, because the supporting film is not easily peeled off from the base film so that workability to peel off the supporting film from the base film of flexible functional element becomes worse. Moreover, the peel strength more than 40 g/cm increases risks of elongation of the flexible functional element, deterioration of the transparent conductive layer caused by a damage such as a crack, and a partial adhesion of the weak adhesive layer onto the surface of the base film, which may be caused by forcibly peeling off the supporting film from the base film.

Depending on the kind of the flexible functional element, the flexible transparent conductive film may be subjected to a heat treatment (for example, at about 120 to 140° C.). Even in this case, the weak adhesive layer needs to have the above-described peel strength after the heat treatment process. The material of the weak adhesive layer is thus required to have heat resistance. Further, the flexible transparent conductive film may be subjected to ultraviolet curing treatment during the production process, so that the material of the weak adhesive layer in this case needs to have ultraviolet resistance.

When the flexible functional element is produced through the heat treatment step as described above, it is desirable that the flexible transparent conductive film does not largely vary in size by the heat treatment. Specifically, after and before the heat treatment, each of the dimension change ratios of the flexible transparent conductive film in the machine direction (MD) and in the transverse direction (TD) is preferably 0.3% or less, more preferably 0.15% or less, even more preferably 0.1% or less. It is to be noted that the dimension change ratio of the plastic film associated with heat treatment generally denotes the shrinkage ratio.

It is not preferable that any one of the dimension change ratios (shrinkage ratio) of the plastic film in the machine direction (MD) and in the transverse direction (TD) exceeds 0.3% for the following reasons. That is to say, when the flexible transparent conductive film is used in, for example, a flexible dispersion-type EL element, a plurality of layers such as a fluorescent layer, a dielectric layer, and a rear electrode layer are successively laminated onto the flexible transparent conductive film. Whenever each layer is formed, a forming paste is applied to form a pattern, and then dried and heated for curing. Thus, a dimension change (shrinkage) occurs whenever each layer is subjected to the heating and curing treatment. As a result, misalignment of the pattern caused by the dimension change may exceed a limit deemed acceptable for the product quality of the dispersion-type EL element.

The dimension change ratio can be decreased by methods such as using a low-thermal-shrinkage type base film which is thermally shrunken in advance, using a base film lined with a low-thermal-shrinkage type supporting film, thermally shrinking a base film or a base film lined with a supporting film in advance, or thermally shrinking the flexible transparent conductive film as a whole.

As described above, the flexible transparent conductive film of the present invention has the first and the second transparent conductive layers, which are laminated on a base film in any order and are strongly adhered to each other. The first transparent conductive layer mainly includes a conductive oxide and is formed by a physical or chemical vapor deposition method, whereas the second transparent conductive layer mainly includes conductive oxide fine particles and a binder matrix and is formed by a coating method. As illustrated in for example FIG. 3, a first transparent conductive layer 2a and a second transparent conductive layer 3a may be laminated in this order on a base film 1. Alternatively, these layers may be laminated in the reverse order as illustrated in FIG. 4. Specifically, the second transparent conductive layer 3a and the first transparent conductive layer 2a may be laminated in this order on the base film 1.

Each of the first transparent conductive layer 2a and the second transparent conductive layer 3a may be formed to fully cover one side of the base film 1, or to cover only a required region of the side. For example, there may be a case where the first transparent conductive layer 2a is formed on a whole surface of the base film 1, and the second transparent conductive layer 3a is formed (pattern-formed) only on a predetermined region on the first transparent conductive layer 2a, or vice versa. The second transparent conductive layer 3a is formed by the coating method, which allows formation of a pattern with ease by applying a coating liquid for forming a transparent conductive layer. As described above, it is possible to create transparent conductive layers excellent in flexibility on only a required region (area) on the base film 1 by forming the first transparent conductive layer 2a to have a specified pattern and/or by forming the second transparent conductive layer 3a to have a specified pattern. Furthermore, the amount of the coating liquid necessary for forming the transparent conductive layer can be saved, which can reduce the material cost of the flexible transparent conductive film.

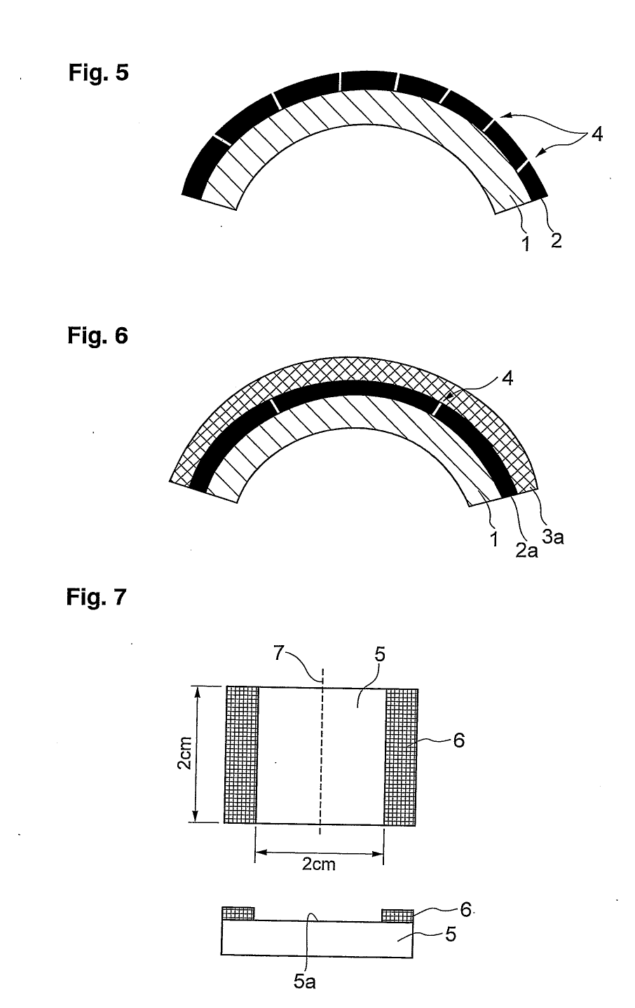

The reason why the flexible transparent conductive film of the present invention is excellent in flexibility is described in more detail below. As illustrated in for example FIG. 5, when a transparent conductive film such as a conventional sputtered ITO film having a transparent conductive layer 2 formed on a base film 1 by the vapor deposition method is bent, many cracks 4 are generated in the transparent conductive layer 2 since the transparent conductive layer 2 is extremely brittle. The conductivity of these sections having the cracks 4 are completely damaged, so that the resistance value of the transparent conductive layer 2 rises largely.

On the other hand, as illustrated in FIG. 6, when a transparent conductive film of a specific example of the present invention having such a structure that a first transparent conductive layer 2a formed by a vapor deposition method and a second transparent conductive layer 3a formed by a coating method are laminated on a base film 1 is bent, the first transparent conductive layer 2a is restrained from being cracked, even though the first transparent conductive layer 2a itself is very brittle. This is because the second transparent conductive layer 3a excellent in flexibility strongly adheres to and protects the first transparent conductive layer 2a. Furthermore, even though some cracks 4 are generated in the first transparent conductive layer 2a, each of the sections having the cracks 4 is electrically connected through the second transparent conductive layer 3a. Thus, the transparent conductive layer as a whole retains its conductivity, and effectively suppresses the deterioration of the resistance value.

When the first transparent conductive layer 2a and the second transparent conductive layer 3a are laminated in this order on the base film 1, the first transparent conductive layer 2a is sandwiched between the second transparent conductive layer 3a and the base film 1, which forms a firmly fixed structure. This structure provides more advantage with regard to restraining the generation of cracks in the first transparent conductive layer 2a by protective capability of the second transparent conductive layer 3a as compared with a structure having the layers laminated in the reversed order. On the other hand, with regard to an effect of sustaining the conductivity of the transparent conductive layer as a whole by way of the second transparent conductive layer 3a when the crack in the first transparent conductive layer 2a has been generated, both of the above lamination structures provide similar effects regardless of the lamination order of the first transparent conductive layer 2a and the second transparent conductive layer 3a.

The conductive oxide used in the first transparent conductive layer is one which mainly includes one or more materials selected from the group consisting of indium oxide, tin oxide, and zinc oxide. Examples thereof include indium tin oxide (ITO), indium zinc oxide (IZO), indium-tungsten oxide (IWO), indium-titanium oxide (ITiO), indium zirconium oxide, tin antimony oxide (ATO), fluorine tin oxide (FTO), aluminum zinc oxide (AZO), and gallium zinc oxide (GZO). Materials of the conductive oxide are not limited to the above examples as long as they have transparency and conductivity. Among them, the ITO fine particles are preferable because the ITO fine particles have the highest properties.

The physical or chemical vapor deposition method for forming the first transparent conductive layer may be, for example, sputtering, ion plating, vacuum evaporation, thermal CVD, photo CVD, Cat-CVD (Catalytic Chemical Vapor Deposition), or MOCVD (Metal Organic Chemical Vapor Deposition), which are used widely.

The first transparent conductive layer obtainable by one of the above-described various methods has a structure of an extremely dense film made of the conductive oxide. Examples of such film may be, for example, an amorphous film, a crystalline film, a hybrid film having both amorphous and crystal, or the like, which depends on the deposition condition. The amorphous film is a non-crystalline homogeneous film, as represented by the word itself. This film is generally formed at low temperature, which enables formation of the film on a plastic film poor in heat resistance. However, the amorphous film has lower conductivity and durability (such as acid resistance and high-temperature and high-humidity resistance) than the crystalline film. On the other hand, the crystal film has a structure in which conductive oxide crystals are linked with each other through crystal grain boundaries. Since a certain level of high temperature is necessary for crystallization, it is difficult to form the film on a plastic film poor in heat resistance. The crystalline film is however excellent in conductivity and durability. Both of the amorphous film and the crystalline film have structures of dense films formed of only the conductive oxide and have substantially no pore. Therefore, as compared with the transparent conductive film formed by coating, which includes conductive oxide particles and a binder matrix as described above, both of these amorphous and crystalline films have excellent conductivity, even though poor in flexibility, brittle, and easily cracked.

The first transparent conductive layer of the present invention may have any film structure such as the amorphous film, the crystalline film, and the hybrid film having both amorphous and crystal, which can be properly selected in accordance with a flexible functional element for which the flexible transparent conductive film is used. For reference, when a PET film is used as the base film, either type of a sputtered ITO film whether amorphous type or a crystalline type can be easily available from the market, since the PET film has a heat resistance of up to about 150° C. (the amorphous type sputtered ITO film, which is easily produced, is less expensive than the crystalline type sputtered ITO film).

The first transparent conductive layer has a relatively smooth surface under ordinary film-forming conditions. Specifically, the amorphous film has the average surface roughness (Ra) of from 0.5 to 1 nm, whereas the crystalline film has that of from 3 to 5 nm. In the case of forming the second transparent conductive layer by the coating method on the first transparent conductive layer, it is preferable to form fine irregularities on the surface of the first transparent conductive layer. These fine irregularities bring about anchor effect, so that the binder matrix in the second transparent conductive layer is strongly bonded to the fine irregularities of the first transparent conductive layer, which makes it possible to increase the adhesive strength between these layers. It is to be noted that the fine irregularities on the surface of the first transparent conductive layer may be formed by adjusting the film-forming conditions. Alternatively, the fine irregularities may be formed by forming fine irregularities on the surface of the base film in advance, and then forming the first transparent conductive layer evenly thereon.

The second transparent conductive layer may be formed by a coating method which will be described hereinbelow. Conductive oxide fine particles and a binder component serving as a binder matrix are dispersed in a solvent to prepare a coating liquid for forming the transparent conductive layer. The coating liquid is applied onto the base film or the first transparent conductive layer, and then dried to form a coating layer. If necessary, the coating layer may be subjected to compression treatment, which will be described later. Thereafter, the binder component is cured to form the second transparent conductive layer. Since the second transparent conductive layer mainly includes the conductive oxide particles and the binder matrix as described above, it has an excellent flexibility even though poor in conductivity as compared with the first transparent conductive layer.

When the first transparent conductive layer mainly including a conductive oxide is directly formed on the base film by a vapor deposition method, or the second transparent conductive layer mainly including conductive oxide fine particles and a binder matrix is directly formed on the base film by a coating method, an adhesion-promoting treatment may be applied to the base film in advance so as to increase the adhesive strength to the first transparent conductive layer or the second transparent conductive layer. Specific examples of such treatments include plasma treatment, corona discharge treatment, and radiation treatment of short-wavelength ultraviolet rays. On the other hand, when the second transparent conductive layer mainly including conductive oxide fine particles and a binder matrix is directly applied on the first transparent conductive layer by coating method, an adhesion-providing agent may be added to the coating liquid for forming the transparent conductive layer so as to increase the adhesive strength to the first transparent conductive layer made of a conductive oxide. Examples of such adhesion-providing agent may include a coupling agent of a silicon series, titanium series, or the like.

The conductive oxide fine particles used in the second transparent conductive layer may be ones which mainly include one or more selected from the group consisting of indium oxide, tin oxide and zinc oxide. Examples thereof include indium tin oxide (ITO) fine particles, indium zinc oxide (IZO) fine particles, indium-tungsten oxide (IWO) fine particles, indium-titanium oxide (ITiO) fine particles, indium zirconium oxide fine particles, tin antimony oxide (ATO) fine particles, fluorine tin oxide (FTO) fine particles, aluminum zinc oxide (AZO) fine particles, and gallium zinc oxide (GZO) fine particles. The conductive oxide fine particles are not limited to the above examples as long as they have transparency and conductivity. Among them, the ITO fine particles are preferable because such particles have the highest properties.

The average particle diameter of the conductive oxide fine particles is preferably from 1 to 500 nm, more preferably form 5 to 100 nm. If the average particle diameter is less than 1 nm, the production of the coating liquid for forming the transparent conductive layer, which will be described later, becomes difficult. Moreover, the resistance value of the resultant transparent conductive layer becomes high. On the other hand, if the average particle diameter is more than 500 nm, the conductive oxide fine particles easily sediment in the coating liquid. Thus, the handling of the coating liquid becomes difficult, and additionally it becomes difficult to simultaneously attain both high transmittance and low resistance value in the transparent conductive layer. It is to be noted that the average particle diameter of the conductive oxide fine particles represents a value observed with a transmission electron microscope (TEM).

The binder component in the coating liquid for forming the transparent conductive layer has a function to bond the conductive oxide fine particles to each other which increases the conductivity and the strength of the film, and has a function to increase the adhesive strength with the underlying. The binder component also has a function for the transparent conductive layer to gain solvent resistance, when the transparent conductive layer may have a risk of deterioration by an organic solvent contained in each of the printing pastes, which are respectively applied in the lamination printing steps to form various functional films in the production process for the flexible functional element.

The organic solvent having a capability to easily deteriorate the transparent conductive layer includes such a solvent that easily swell or dissolve various resins or organic binders in the transparent conductive layer. Examples of such solvents include ketone series, ester series, and alkylamide series solvents, toluene, N-methyl-2-pyrrolidone, γ-butyrolactone, or the like. On the contrary, organic solvents that hardly deteriorate the transparent conductive layer include, although depending on the type of an organic binder for the transparent conductive layer, aqueous series, alcohol series, glycol series solvents, or the like. The binder may include an organic binder, an inorganic binder, or an organic-inorganic hybrid binder. The binder may be appropriately selected so that the binder plays the above-described functions in consideration of condition of the underlying, etc. on which the coating liquid for forming the transparent conductive layer is applied.

Although a thermoplastic resin such as acrylic resin or polyester resin can be used for the organic binder, the organic binder preferably has a property of solvent resistance as described above in order to prevent the deterioration of the transparent conductive layer, and other reasons. For the purposes, the organic binder needs to be a crosslinkable resin. Thus, the organic binder is desirably selected from thermosetting resin, cold-setting resin, ultraviolet curable resin, electron beam curable resin, or the like. Examples of the thermosetting resin include epoxy resin, and fluorine-contained resin. Examples of the cold-setting resin include two components type resins such as epoxy resin and urethane resin. Examples of the ultraviolet curable resin include a resin having various kinds of oligomers, monomers, and photoinitiators. Examples of the electron beam curable resin include a resin having various kinds of oligomers, and monomers. These examples are cited for the purpose of illustration and not limitation.

In order to strongly adhere the second transparent conductive layer and the first transparent conductive layer (conductive oxide layer such as a sputtered ITO layer) to each other, it is desirable that the organic binder in the second transparent conductive layer adheres to the conductive oxide layer constituting the first transparent conductive layer. For this purpose, it is preferable that the organic binder has a hydroxyl group (—OH). This is because the organic binder having the hydroxyl group strongly bonds (hydrogen-bonds) to the surface of the conductive oxide layer of the first transparent conductive layer via the hydroxyl moiety, so as to have an effect of increasing the adhesive strength between the first transparent conductive layer and the second transparent conductive layer.

Examples of the organic binder having the hydroxyl group (—OH) include, but not limited to, various hydroxyl-modified resins which are modified from the above-described thermoplastic resin, thermosetting resin, cold-setting resin, ultraviolet curable resin, electron beam curable resin, and the like, such that each of the hydroxyl-modified resins is obtained by introducing the hydroxyl group (—OH) into a resin originally having no hydroxyl group (—OH). Examples of the organic binder having the hydroxyl group (—OH) further include acryl polyol resin, polyester polyol resin, phenoxy resin, bisphenol A type (DGEBA [bisphenol A diglycidyl ether] type) epoxy resin, and the like.

Material other than the above-described resins containing the hydroxyl group (—OH) can be used as the organic binder as long as it has a capability to strongly adhere to the first transparent conductive layer (conductive oxide layer such as a sputtered ITO layer), and has a certain level of strength (hardness, toughness, etc.).

Example of the inorganic binder may include one which mainly includes silica sol, alumina sol, zirconia sol, titania sol, or the like. For example, the silica sol may be a polymer obtained by adding water and an acid catalyst to a tetraalkyl silicate to hydrolyze the silicate, and advancing the dehydropolycondensation thereof. Alternatively, the silica sol may be a polymer obtained by advancing a further hydrolysis and dehydropolycondensation on a commercially available solution of an alkyl silicate which is already polymerized into a tetramer or pentamer.

If the dehydropolycondensation advances too much, the solution viscosity rises so that the solution is finally solidified. Thus, the degree of the dehydropolycondensation is adjusted to not more than the upper limit viscosity permitting the solution to be applied onto a transparent substrate. The degree of the dehydropolycondensation is not particularly limited as long as the degree is at a level not more than the upper limit viscosity. Considering the strength and the weather resistance of the film, and others, the degree is preferably from about 500 to 50000 in weight-average molecular weight. The alkyl silicate hydrolyzed and polymerized product (silica sol) substantially completes its dehydropolycondensation reaction (crosslinking reaction) during the heating process after the coating liquid for forming the transparent conductive layer is applied and dried. Thus, a hard silicate binder matrix (binder matrix mainly including silicon oxide) is formed. The dehydropolycondensation starts immediately after the film is dried. As time advances, the film is firmly cured to such an extent that the conductive oxide fine particles cannot be shifted from each other. Thus, when the inorganic binder is used, it is necessary that compression treatment described later is performed as soon as possible after the coating liquid for forming the transparent conductive layer is applied and dried.

Since the inorganic binder has hydroxyl group (—OH) the binder basically tends to strongly adhere to the conductive oxide layer of the first transparent conductive layer. However, when the inorganic binder is used alone, the curing shrinkage force of the inorganic binder is large during the curing of the film. Thus, the internal stress of the film becomes high so that the adhesive property may be damaged. Moreover, the flexibility of the inorganic binder matrix itself is not very high. For these reasons, the inorganic binder is more preferably used as an organic-inorganic hybrid binder, in which the inorganic binder is combined with an organic binder, as described below.

Examples of the organic-inorganic hybrid binder include one in which the above-described silica sol is partially modified with an organic functional group, or one which mainly includes a coupling agent of various type such as a silane coupling agent. The organic-inorganic hybrid binder is made by introducing an organic component into an inorganic binder to give softness so that the internal stress of the film can be relaxed. Thus, unlike the case using the inorganic binder alone, the hybrid binder has a feature not likely to cause the above-described problem of damaging the adhesive property. Even though use of the inorganic binder or the organic-inorganic hybrid binder for the second transparent conductive layer essentially provides an excellent solvent resistance, appropriate selection of the binder type is necessary so as not to deteriorate the adhesive strength onto the underlying, that is, the base film or the first transparent conductive layer, and not to deteriorate the flexibility and other properties of the second transparent conductive layer.

The mixing ratio of the conductive oxide fine particles and the binder component in the coating liquid for forming the transparent conductive layer used in the present invention depends on the kind of the coating liquid for forming the transparent conductive layer and the specific method for forming the transparent conductive layer by coating. Assuming that the specific gravity of the conductive oxide fine particles and that of the binder component are about 7.2 (the specific gravity of ITO) and about 1.2 (the specific gravity of an ordinary organic resin binder), respectively, the weight ratio of the conductive oxide fine particles to the binder component is preferably from 75:25 to 97:3, more preferably from 80:20 to 95:5, even more preferably from 85:15 to 93:7 for the following reasons. That is to say, if the proportion of the binder component is large as compared with the ratio of 75:25, the resistance value of the second transparent conductive layer becomes too high. On the other hand, if the proportion of the binder component is small as compared with the ratio of 97:3, the strength of the second transparent conductive layer decreases and further a sufficient adhesive strength to the underlying, i.e., the base film or the first second transparent conductive layer is not obtained.

The coating liquid for forming the transparent conductive layer may be prepared by a method described hereinafter. First, conductive oxide fine particles are mixed with a solvent and an optional dispersing agent, and then the mixture is subjected to dispersing treatment to make a conductive-oxide-fine-particle dispersion. Examples of the dispersing agent include various coupling agents such as a silane coupling agent, various polymer dispersing agents, and various surfactants such as anionic series, nonionic series, and cationic series. These dispersing agents may be appropriately selected depending on the kind of conductive oxide fine particles used and the method of the dispersing treatment. Even when a dispersing agent is not used at all, a good dispersion state may be obtained depending on a combination of the conductive oxide fine particles and the solvent, and on the dispersing method. Since the use of the dispersing agent may deteriorate the resistance value or the weather resistance of the film, a coating liquid for forming the transparent conductive layer without using the dispersing agent is most preferable. As for the dispersing treatment, a widely used method can be used, and such method includes ultrasonic treatment, a homogenizer, a paint shaker, or a bead mill.

A binder component is added to the resultant conductive-oxide-fine-particle dispersion, and furthermore, concentration of the conductive oxide fine particles, the solvent composition, and other component are adjusted. Accordingly, a coating liquid for forming the transparent conductive layer is obtained. The above procedure of adding the binder component to the dispersion of the conductive oxide fine particles is not described for limitation. Alternatively, the binder component may be added in advance before the step of dispersing the conductive oxide fine particles. The concentration of the conductive oxide fine particles may be appropriately adjusted depending on the coating method to be used.

The solvent used in the coating liquid for forming the transparent conductive layer is not particularly limited, and may be appropriately selected depending on factors such as the coating method to be used, conditions of forming the film, the material of the base film in the case of the underlying being the base film. Examples thereof include, but not limited to, water, alcohol solvents such as methanol (MA), ethanol (EA), 1-propanol (NPA), isopropanol(IPA), butanol, pentanol, benzyl alcohol and diacetone alcohol (DAA), ketone solvents such as acetone, methyl ethyl ketone (MEK), methyl propyl ketone, methyl isobutyl ketone (MIBK), cyclohexanone and isophorone, ester solvents such as ethyl acetate, butyl acetate, isobutyl acetate, amyl formate, isoamyl acetate, butyl propionate, isopropyl butyrate, ethyl butyrate, butyl butyrate, methyl lactate, ethyl lactate, methyl oxyacetate, ethyl oxyacetate, butyl oxyacetate, methyl methoxyacetate, ethyl methoxyacetate, butyl methoxyacetate, methyl ethoxyacetate, ethyl ethoxyacetate, methyl 3-oxypropionate, ethyl 3-oxypropionate, methyl 3-methoxypropionate, ethyl 3-methoxypropionate, methyl 3-ethoxypropionate, ethyl 3-ethoxypropionate, methyl 2-oxypropionate, ethyl 2-oxypropionate, propyl 2-oxypropionate, methyl 2-methoxypropionate, ethyl 2-methoxypropionate, propyl 2-methoxypropionate, methyl 2-ethoxypropionate, ethyl 2-ethoxypropionate, methyl 2-oxy-2-methylpropionate, ethyl 2-oxy-2-methylpropionate, methyl 2-methoxy-2-methylpropionate, ethyl 2-ethoxy-2-methylpropionate, methyl pyruvate, ethyl pyruvate, propyl pyruvate, methyl acetoacetate, ethyl acetoacetate, methyl 2-oxobutanoate and ethyl 2-oxobutanoate, glycol derivatives such as ethylene glycol monomethyl ether (MCS), ethylene glycol monoethyl ether (ECS), ethylene glycol isopropyl ether (IPC), ethylene glycol monobutyl ether (BCS), ethylene glycol monoethyl ether acetate, ethylene glycol monobutyl ether acetate, propylene glycol methyl ether (PGM), propylene glycol ethyl ether (PE), propylene glycol methyl ether acetate (PGM-AC), propylene glycol ethyl ether acetate (PE-AC), diethylene glycol monomethyl ether, diethylene glycol monoethyl ether, diethylene glycol monobutyl ether, diethylene glycol monomethyl ether acetate, diethylene glycol monoethyl ether acetate, diethylene glycol monobutyl ether acetate, diethylene glycol dimethyl ether, diethylene glycol diethyl ether, diethylene glycol dibutyl ether, dipropylene glycol monomethyl ether, dipropylene glycol monoethyl ether and dipropylene glycol monobutyl ether, benzene derivatives such as toluene, xylene, mesitylene and dodecylbenzene, formamide (FA), N-methylformamide, dimethylformamide (DMF), dimethylacetoamide, dimethylsulfoxide (DMSO), N-methyl-2-pyrrolidone (NMP), γ-butyrolactone, ethylene glycol, diethylene glycol, tetrahydrofuran (THF), chloroform, mineral spirits, and terpineol; and mixtures thereof.

Compression treatment, which is optionally applied to the coating layer obtained by applying and drying the coating liquid for forming the transparent conductive layer in the formation of the second transparent conductive layer, will be hereinafter described. The coating layer is subjected to compression treatment together with the base film or together with the first transparent conductive layer and the base film. Thereafter, the binder component in the coating layer which is compression treated is cured. The compression treatment increases the filling density of the conductive fine particles in the second transparent conductive layer, which not only decreases scattering of light and improves optical property of the second transparent conductive layer, but also greatly improves the conductivity and the film strength. It is to be noted that whether applying the compression treatment to the second transparent conductive layer or not may be appropriately determined considering factors, such as the kind of the coating liquid for forming the transparent conductive layer, properties required for the transparent conductive layer, the kind of a flexible functional element to which the flexible transparent conductive film is applied, the environment condition of the element to be used, production cost of the flexible transparent conductive film (the production cost may increase when the compression treatment is applied).

For example, the compression treatment may be performed in such a manner that the based film on which the coating liquid for forming the transparent conductive layer has been applied and dried is rolled with metallic rolls that are hard chromium plated, or with other rolling means. In this case, the rolling pressure of the roll is preferably from 29.4 to 490 N/mm (30 to 500 kgf/cm) in linear pressure, more preferably from 98 to 294 N/mm (100 to 300 kgf/cm) in linear pressure. If the linear pressure is less than 29.4 N/mm (30 kgf/cm), the effect of improving the resistance value of the transparent conductive layer by the compression treatment becomes insufficient. On the other hand, if the linear pressure is more than 490 N/mm (500 kgf/cm), the size of an apparatus for the compression becomes large. Additionally, the base film or the supporting film may be distorted, and when the coating liquid has been applied on the first transparent conductive layer, the first transparent conductive layer may be cracked. The rolling pressure per unit area (N/mm²) of the metallic roll in the rolling treatment is a value obtained by dividing the linear pressure by the nip width (the width of the region where the transparent conductive film is crashed with the metallic rolls in the contact portion between the metallic roll and the transparent conductive film). The nip width, which depends on the diameter of the metallic rolls and the linear pressure, is from about 0.7 to 2 mm when the roll diameter is about 150 mm.

When a thin base film having a thickness of 3 to 50 μm is used, provision of the supporting film before the compression treatment can effectively prevent the base film from being distorted or wrinkled. When applying the compression treatment with the metallic rolls having hard chrome plating, use of mirror plane rolls, which are metallic rolls having very fine irregularities on a surface thereof, makes it possible to create a transparent conductive layer having an extremely smooth surface after the compression treatment. This is because even the coating layer obtained by applying the coating liquid for forming the transparent conductive layer has protrusions, such protrusions can be made physically smooth by the compression treatment with the metallic rolls. It is extremely preferable that the transparent conductive layer surface has good smoothness, because smooth surface has an effect of preventing short circuit between electrodes and generation of a defect on the flexible functional elements of various types described below.

By using the above-described method, the flexible transparent conductive film of the present invention is completed. A flexible functional element to which the flexible transparent conductive film of the present invention can be applied will be hereinafter described. Examples of such flexible functional element include a liquid crystal display element, an organic EL element, a dispersion-type EL element, an electronic paper element, a solar cell, and a touch panel, and the like.

The liquid crystal display element is a nonluminous electronic display element which is widely used in a display of a mobile phone, a PDA (Personal Digital Assistant), a PC (Personal Computer), or the like, and is classified into a simple matrix type (passive matrix type) and an active matrix type. The active matrix type is superior from viewpoints of image quality and response speed. A basic structure of the liquid crystal display element is one in which a liquid crystal is sandwiched between transparent electrodes, and liquid crystal molecules are oriented by voltage-driving so as to perform display. Besides the transparent electrodes, practical elements are provided with an additional lamination such as a color filter, a retardation film, a polarizing film, and the like.

There are different types of liquid crystal display elements which include a polymer dispersion-type liquid crystal element (hereinafter abbreviated to a PDLC element) and a polymer network liquid crystal element (hereinafter abbreviated to a PNLC element), which are used in an optical shutter for a window or the like, or in a display. Basic structures of both of these elements are similar to that described above in which a liquid crystal layer is sandwiched between electrodes (at least one thereof is a transparent electrode, and the transparent conductive layer of the present invention is used therein) and liquid crystal molecules are oriented by voltage-driving, so as to generate change between transparency and opaqueness in the external appearance of the liquid crystal layer. Unlike the above-described liquid crystal display element, an actual element of this type needs no retardation film nor polarizing film, which makes it possible to simplify the structure of the element.

The PDLC element has a structure in which micro-encapsulated liquid crystal is dispersed in a polymer resin matrix. Whereas the PNLC element has a structure in which a liquid crystal fills up mesh portions in the network of resin. In general, the PDLC element has high percentage of resin content in the liquid crystal layer, and therefore an alternating driving voltage of several tens of volts or more (for example, about 80 V) is necessary. In contrast, the PNLC element has a feature of being able to achieve low percentage of resin content in the liquid crystal layer, which makes it possible to drive the element as low as several volts to 15 V in alternating voltage.

Unlike the liquid crystal display element, the organic EL element is a self-emitting element which can provide a high luminance at low driving voltage, and thus this element is expected as an image displaying apparatus such as a display unit. This element has a structure in which a hole injection layer made of a conductive polymer such as a polythiophene derivative, an organic luminous layer (a low-molecular-weight luminous layer formed by vapor deposition, or a polymeric luminous layer formed by coating), a cathode electrode layer (a metal layer having good electron injection performance into the luminous layer and low work function, such as magnesium (Mg), calcium (Ca), and aluminum (Al)), and a gas barrier coating layer (or sealing treatment with a metal or glass), which are successively formed on a transparent conductive layer as an anode electrode layer. The gas barrier coating layer is necessary to prevent deterioration of the organic EL element and thus needs to have barrier performance against oxygen and water vapor. With regard to, for example, barrier against water vapor, the gas barrier coating layer needs to have a very high barrier performance of about 10⁻⁵ g/m²/day or less in water vapor permeability.

The dispersion-type EL element is a self-emitting element which emits light when an intense alternating electric field is applied to its layer including fluorescent particles. The element has been conventionally used in a backlight for a liquid crystal display of a mobile phone, a remote controller or the like, and in some other members. In recent year, the element is beginning to incorporated into, as a new application, a light source of a key input component (key pad) for various devices such as a mobile phone, a remote controller, a PDA, a laptop PC and other portable information terminals. When the element is used as the key pad, the element is required to be formed as thin as possible so that the element becomes flexible. Further, the element is required to have keystroke durability and a good clicking feeling for key operation. A basic structure of this element has at least a fluorescent layer, a dielectric layer and a rear electrode layer, which are successively formed on a transparent conductive layer as a transparent electrode by screen printing or the like. In an actual device thereof, it is general that a current collecting electrode made of silver or the like, an insulating protective layer, and the like are further formed.

The electronic paper element is a nonluminous electronic display element which does not emit light by itself, and has memory effect which keeps a displaying image as it is even when the power source is switched off. The element is expected as a display device for displaying characters. Examples of its displaying methods include an electrophoretic method in which colored particles are shifted in a liquid between electrodes by electrophoresis, a twist ball method in which particles having dichroism are rotated in an electric field to develop color, a liquid crystal method in which, for example, a cholesteric liquid crystal is sandwiched between transparent electrodes to attaining displaying, a powdery system method in which colored particles (toner) or electronic liquid powder (quick response liquid powder) are shifted in the air to attain displaying, an electrochromic method in which color development is attained based on electrochemical oxidation and reduction effect, and an electrodeposition method in which a metal is precipitated or dissolved by electrochemical oxidation and reduction, and display is attained by a color change associated with the precipitation or dissolution. In order to keep stability of these electronic paper elements of the various methods, it is necessary to prevent water vapor from being incorporated into their display layer. For example, although depending on the method, the element is required to have water vapor permeability of from 0.01 to 0.1 g/m²/day.

The solar cell is a power generating element for converting rays of sun to electric energy, and examples thereof include a silicon solar cell, a CIS solar cell (copper-indium-selenium thin film), a CIGS solar cell (copper-indium-gallium-selenium thin film), a dye sensitized solar cell, and an organic thin film solar cell. For example, an amorphous silicon solar cell has a transparent electrode, a semiconductor power-generating layer (amorphous silicon), and a metallic electrode, which are successively formed on a transparent substrate.

The touch panel is a position input element, and is classified into a resistive type, a capacitive type and other types. For example, the resistive type touch panel has a structure in which two transparent conductive films as coordinate-detecting resistance films for detecting a coordinate are adhered to each other having a dot-shape transparent spacer therebetween. The transparent conductive films need to have hitting durability, and their transparent conductive layers need to have flexibility so as not to generate a crack.

In any one of the flexible functional elements, it is becoming more and more important that the element is made thinner, lighter and more flexible. These issues can be attained by using the flexible transparent conductive film of the present invention, that is, by forming a flexible functional element on the transparent conductive layer of the flexible transparent conductive film of the present invention. Examples of such elements include a liquid crystal display element, an organic EL element, a dispersion-type EL element, an electronic paper element, a solar cell, and a touch panel.

It is to be noted that either a simple matrix (passive matrix) or an active matrix may be used as the displaying method for the flexible functional element including the liquid crystal element, the organic EL element and the electronic paper element, which have display functions. For example, the simple matrix manner may be accomplished by sandwiching a functional layer (display layer) between two electrode-attached films each having a line-patterned electrode such that their line-patterned electrodes are orthogonal to each other and their electrode surfaces face each other. The flexible transparent conductive film of the present invention can be applied to at least one of the electrode-attached films described above by forming the first and second transparent conductive layers having line patterns.

On the other hand, the active matrix manner may be accomplished by sandwiching a functional layer (display layer) between a transparent conductive film having a transparent conductive layer (common electrode) on a whole surface thereof, and a backside film (back plane) having, in each display pixel, a TFT (thin film transistor) connected to both a scanning wiring and a signal wiring and a pixel electrode, such that their electrode surfaces face each other. The flexible transparent conductive film of the present invention can be applied to the common electrode film as it is, or to the backside film by forming the first and second transparent conductive layers having patterns of the pixel electrodes. It is to be noted that the TFT is preferably formed by an organic TFT, which is better in flexibility than silicon TFT. The organic TFT is also better in cost than silicon TFT since the organic TFT can be formed on a plastic film by coating (printing).

As described above, the flexible transparent conductive film is used as the transparent electrode material for various flexible functional elements according to the present invention such as a liquid crystal display element, an organic EL element, a dispersion-type EL element, an electronic paper element, a solar cell, a touch panel. Since the flexible transparent conductive film has transparency and conductivity which are equivalent to those of a sputtered ITO film, and has excellent in flexibility, these flexible functional elements can be made light and thin, and are also easy to handle. For this reason, these flexible functional elements can be applied to various devices including thin devices such as cards (an IC card, a credit card, a prepaid card, etc.), and portable devices (a mobile phone, an electronic book, a PDA, etc.).

### Examples

Examples of the present invention will be hereinafter specifically described, however the present invention is not limited to these examples. In the examples, “%” and “part(s)” represent “% by weight” and “part(s) by weight”, respectively, unless otherwise specified.

### Example 1

36 g of granular ITO fine particles (trade name: SUFP-HX, manufactured by Sumitomo Metal Mining Co., Ltd.) having an average particle diameter of 0.03 μm were mixed with 24 g of methyl isobutyl ketone (MIBK) and 36 g of cyclohexanone as solvents, and the mixture was subjected to dispersing treatment. Thereafter, thereto were added 3.8 g of a urethane acrylate ultraviolet curable resin binder containing hydroxyl groups, 0.2 g of a photoinitiator (DAROCUR 1173) and a trace amount of a silane coupling agent. The components are sufficiently stirred to obtain a coating liquid (liquid A) for forming a transparent conductive layer wherein ITO fine particles having an average dispersion particle diameter of 125 nm were dispersed. The weight ratio of the conductive oxide fine particles (ITO fine particles) to the binder component (the resin binder+the photopoinitiator) was 90:10.

A low heat shrinkage type PET film (thickness: about 100 μm, transmittance=89.8%, and haze value=1.9%) as a base film was subjected to corona discharge treatment, and then an amorphous ITO film (first transparent conductive layer, film thickness: about 0.02 μm) was formed on the treated surface by sputtering. Next, the coating liquid (liquid A) for forming the transparent conductive layer was applied on this sputtered ITO film (first transparent conductive layer, surface resistivity=300 Ω/square, transmittance=96.5%, and haze value=0.8%) by wire bar coating (wire diameter: 0.10 mm), and then dried at 60° C. for 1 minute.

Thereafter, the workpiece was subjected to rolling treatment (linear pressure: 200 kgf/cm=196 N/mm, and nip width: 0.9 mm) with metallic rolls having a diameter of 100 mm and hard chromium plated, and further the binder component was cured (under nitrogen atmosphere at 100 mW/cm² for 2 seconds) through a high-pressure mercury lamp to form a second transparent conductive layer (film thickness: about 0.5 μm) composed of the ITO fine particles filled densely and the binder matrix on the sputtered ITO film. In this way, a flexible transparent conductive film according to Example 1 was obtained which was composed of the base film, the first transparent conductive layer formed by the vapor deposition method, and the second transparent conductive layer formed by the coating method.

This flexible transparent conductive film had a dimension change ratio (shrinkage ratio) of about 0.3% when heated. It is to be noted that the dimension change ratio (shrinkage ratio) represents ratio of dimension change (ratio of shrinkage) in the machine direction (MD), which is a lager value out of the dimension change ratio (shrinkage ratio) of the film in the machine direction (MD) and that of the film in the transverse direction (TD) obtained by subjecting the flexible transparent conductive film according to Example 1 to heat treatment (at 150° C. for 30 minutes).

The laminated transparent conductive layers (the first transparent conductive layer formed by the vapor deposition method and the second transparent conductive layer formed by the coating method) had film properties of 92.5% in visible ray transmittance, 2.4% in haze value, and 250 Ω/square in surface resistivity. The surface resistivity tends to temporarily decrease its value immediately after the curing by the influence of irradiation with ultraviolet rays when the binder is cured, accordingly the value was measured after one day from the formation of the transparent conductive layers. The visible ray transmittance and the haze value of the above-described transparent conductive layers represent values of only the transparent conductive layers, and were respectively calculated from calculation formulas 1 and 2 described below.

The visible ray transmittance (%) of the transparent conductive layers=[(the total transmittance of the combination of the transparent conductive layers and the base film)/the transmittance of only the base film]×100 [Calculation formula 1]

The haze value (%) of the transparent conductive layers=(the total haze value of the combination of the transparent conductive layers and the base film)−(the haze value of only the base film) [Calculation formula 2]

The surface resistivity of the transparent conductive layers was measured by use of a surface resistivity meter LORESTAAP (MCP-T400) manufactured by Mitsubishi Chemical Corp. The haze value and visible ray transmittance were measured by use of a haze meter (NDH 5000) manufactured by Nippon Denshoku Industries Co., Ltd. based on JIS K7136 (haze value) and JIS K7361-1 (transmittance).

The adhesive strength between the first and second transparent conductive layers in the flexible transparent conductive film composed of the base film/the first transparent conductive layer/the second transparent conductive layer was evaluated in a tape peeling test according to JIS K5600-5-6 (crosscut test). As a result, a good result of 25/25 (the number of pieces not peeled/the number of all the pieces [5×5=25]) was obtained. In the tape peeling test (crosscut test), the base film and the first transparent conductive layer also adhered strongly to each other, so that no peeling was observed therebetween which is similar to the interface between the first and second transparent conductive layers.

Next, an electrophoretic display layer (thickness: 40 μm) made of microcapsules containing white fine particles and black fine particles was formed on the bilayered film, i.e., the flexible transparent conductive film composed of the first and second transparent conductive layers. Furthermore, a PET film (thickness: 25 μm) coated with a carbon conductive paste was adhered to the display layer such that a surface of the carbon conductive layer faced the display layer.

A silver conductive paste was applied to form a voltage-applying Ag lead line at each end of the bilayered film and the carbon conductive layer, in which the bilayered film composed of the first and second transparent conductive layers and the carbon conductive layer are adhered to each other with the display layer interposed therebetween. In this way, a flexible functional element (electronic paper) (thickness: about 176 μm) according to Example 1 was obtained, which was composed of the base film (thickness: about 100 μm) /the first transparent conductive layer (thickness: about 0.02 μm)/the second transparent conductive layer (thickness: about 0.5 μm)/the display layer (thickness: 40 μm)/the carbon conductive layer (thickness: about 10 μm)/the PET film (thickness: 25 μm).

In order to prevent short circuit between the electrodes, electric shock and others, an insulating paste was used to optionally form an insulating layer as an insulating protective coating on each of the second transparent conductive layer, the carbon conductive layer and voltage-applying Ag lead lines. Since the insulating layer is not a component essential for the present invention, details thereof are omitted. In order to keep the reliability, a gas barrier film (GX-P-F film manufactured by Toppan Printing Co., Ltd., which will be abbreviated to a “GX film” hereinafter) (thickness: about 13 μm) was adhered to the flexible functional element on a side of the flexible transparent conductive film. The other side opposite thereto was also subjected to moisture-proof laminating treatment.

The GX film had a film structure of a PET film (thickness: 12 μm)/vapor-deposited alumina gas barrier layer (thickness: 10 to several tens of nanometers)/silicate-polyvinyl alcohol hybrid coating layer. The water vapor permeability was 0.05 g/m²/day (in a measuring atmosphere of 40° C.×90% relative humidity), the oxygen permeability was about 0.2 cc/m²/day/atm (in a measuring atmosphere of 30° C.×70% relative humidity), the transmittance was 88.5%, and the haze value was 2.3%. A direct-current voltage of 10 V was applied across the voltage-applying lead lines of the flexible functional element (electronic paper) and the polarity thereof was changed repeatedly. As a result, repeated display of white and black was observed.

### Example 2

40 g of the same ITO fine particles as in Example 1 were mixed with 40 g of isophorone as a solvent, and then thereto was added a trace amount of a dispersing agent. A paint shaker was then used to subject the mixture to dispersing treatment, thereby obtaining an ITO fine particle dispersion. To 40 g of this ITO fine particle dispersion were added a resin solution wherein 4.48 g of a crosslinkable acrylpolyol resin binder containing hydroxyl groups (glass transition point (Tg) of the resin before the resin was crosslinked: 102° C., hydroxyl value: 29 KOHmg/g) was dissolved in 17.14 g of isophorone, 0.88 g of an HDI based block isocyanate (MF-K60X, manufactured by Asahi Kasei Corp., solid content [curing agent component]: about 60%), lowest curing temperature: 90° C., NCO: 6.5% by weight) as a curing agent, and a trace amount of a silane coupling agent. The components were sufficiently stirred to obtain a coating liquid (liquid B) for forming a transparent conductive layer in which the ITO fine particles having an average dispersion particle diameter of 120 nm were dispersed. The weight ratio of the conductive oxide fine particles (ITO fine particles) to the binder component (the resin binder+the curing agent) was 80:20. The mole ratio of NCO (isocyanate groups)/OH (hydroxyl groups) was 0.59.

The coating liquid (liquid B) for forming a transparent conductive layer was applied by wire bar coating (linear diameter: 0.075 mm) and then dried at 60° C. for 10 minutes, and further heated at 120° C. for 20 minutes to cure (crosslink) the binder component thermally, thereby forming a second transparent conductive layer (film thickness: about 0.5 μm) composed of the ITO fine particles and the binder matrix on the sputtered ITO film. Other than the above, in a manner similar to Example 1, a flexible transparent conductive film according to Example 2 was obtained, which was composed of the base film/the first transparent conductive layer formed by the vapor deposition method/the second transparent conductive layer formed by the coating method. This flexible transparent conductive film had a dimension change ratio (shrinkage ratio) of about 0.2% when heated.

The laminated transparent conductive layers (the first transparent conductive layer formed by the vapor deposition method and the second transparent conductive layer formed by the coating method) had film properties of 95.5% in visible ray transmittance, 2.8% in haze value, and about 300 Ω/square in surface resistivity. The visible ray transmittance and the haze value of the transparent conductive layers were values of only the transparent conductive layers, and were respectively calculated from the above-described calculation formulas 1 and 2. The surface resistivity was measured after one hour from the formation of the transparent conductive layers in order to avoid the effect of the heat treatment (thermal curing) of the binder component.

The adhesive strength between the first and second transparent conductive layers in the flexible transparent conductive film composed of the base film/the first transparent conductive layer/the second transparent conductive layer was evaluated in a tape peeling test (crosscut test) according to JIS K5600-5-6. As a result, a good result of 25/25 (the number of pieces not peeled/the number of all the pieces [5×5=25]) was obtained. In the tape peeling test (crosscut test), the base film and the first transparent conductive layer also adhered strongly to each other, so that no peeling was observed therebetween which is similar to the interface between the first and second transparent conductive layers.

Next, the flexible transparent conductive film was used in a similar manner as Example 1, and obtained a flexible functional element (electronic paper) (thickness: about 176 μm) according to Example 2, which was composed of the base film (thickness: about 100 μm)/the first transparent conductive layer (thickness: about 0.02 μm)/the second transparent conductive layer (thickness: about 0.5 μm)/the display layer (thickness: 40 μm)/the carbon conductive layer (thickness: about 10 μm)/the PET film (thickness: 25 μm).

In order to keep the reliability, a gas barrier film (GX film, manufactured by Toppan Printing Co., Ltd. (thickness: about 13 μm)) was adhered to the flexible functional element on a side of the flexible transparent conductive film. The other side opposite thereto was also subjected to moisture-proof laminating treatment. A direct-current voltage of 10 V was applied across the voltage-applying lead lines of the flexible functional element (electronic paper) and the polarity thereof was changed repeatedly. As a result, repeated display of white and black was observed.

### Example 3

Instead of the ITO fine particles in Example 1, granular ITO fine particles having an average particle diameter of 0.04 μm (trade name: FS-21, manufactured by Dowa Metals & Mining Co.) were used. Thereto were added isophorone and a trace amount of a dispersing agent. The mixture was subjected to dispersing treatment, thereby obtaining an ITO fine particle dispersion. Other than the above, in a manner similar to Example 2, a coating liquid (liquid C) for forming a transparent conductive layer was obtained in which the ITO fine particles having an average dispersion particle diameter of 135 nm were dispersed. The weight ratio of the conductive oxide fine particles (ITO fine particles) to the binder component (the resin binder+the curing agent) was 80:20. The mole ratio of NCO (isocyanate groups)/OH (hydroxyl groups) was 0.59.

In a manner similar to Example 2 other than using the coating liquid (liquid C) for forming a transparent conductive layer instead of the liquid B, a flexible transparent conductive film according to Example 3 was obtained, which was composed of the base film/the first transparent conductive layer formed by the vapor deposition method/the second transparent conductive layer formed by the coating method. This flexible transparent conductive film had a dimension change ratio (shrinkage ratio) of about 0.2% when heated.

The laminated transparent conductive layers (the first transparent conductive layer formed by the vapor deposition method and the second transparent conductive layer formed by the coating method) had film properties of 95.6% in visible ray transmittance, 3.0% in haze value, and about 300 Ω/square in surface resistivity. The visible ray transmittance and the haze value of the transparent conductive layers were values of only the transparent conductive layers, and were respectively calculated from the above-described calculation formulas 1 and 2. The surface resistivity was measured after one hour from the formation of the transparent conductive layers in order to avoid the effect of the heat treatment (thermal curing) of the binder component.

The adhesive strength between the first and second transparent conductive layers in the flexible transparent conductive film composed of the base film/the first transparent conductive layer/the second transparent conductive layer was evaluated in a tape peeling test (crosscut test) according to JIS K5600-5-6. As a result, a good result of 25/25 (the number of pieces not peeled/the number of all the pieces [5×5=25]) was obtained. In the tape peeling test (crosscut test), the base film and the first transparent conductive layer also adhered strongly to each other, so that no peeling was observed therebetween which is similar to the interface between the first and second transparent conductive layers.

Next, the flexible transparent conductive film was used in a similar manner as Example 1, and obtained a flexible functional element (electronic paper) (thickness: about 176 μm) according to Example 3, which was composed of the base film (thickness: about 100 μm)/the first transparent conductive layer (thickness: about 0.02 μm)/the second transparent conductive layer (thickness: about 0.5 μm)/the display layer (thickness: 40 μm)/the carbon conductive layer (thickness: about 10 μm)/the PET film (thickness: 25 μm).

In order to keep the reliability, a gas barrier film (GX film, manufactured by Toppan Printing Co., Ltd. (thickness: about 13 μm)) was adhered to the flexible functional element on a side of the flexible transparent conductive film. The other side opposite thereto was also subjected to moisture-proof laminating treatment. A direct-current voltage of 10 V was applied across the voltage-applying lead lines of the flexible functional element (electronic paper) and the polarity thereof was changed repeatedly. As a result, repeated display of white and black was observed.

### Example 4

40 g of the same ITO fine particles as in Example 1 were mixed with 40 g of isophorone as a solvent, and then thereto was added a trace amount of a dispersing agent. A paint shaker was then used to subject the mixture to dispersing treatment, thereby obtaining an ITO fine particle dispersion. To 40 g of this ITO fine particle dispersion were added a resin solution wherein 4.76 g of a crosslinkable urethane-modified polyester resin binder containing hydroxyl groups (glass transition point (Tg) of the resin before the resin was crosslinked: about 80° C.) was dissolved in 17.34 g of isophorone, 0.4 g of an HDI based block isocyanate (MF-K60X, manufactured by Asahi Kasei Corp., solid content [curing agent component]: about 60%), lowest curing temperature: 90° C., NCO: 6.5% by weight) as a curing agent, and a trace amount of a silane coupling agent. The components were sufficiently stirred to obtain a coating liquid (liquid D) for forming a transparent conductive layer in which the ITO fine particles having an average dispersion particle diameter of 120 nm were dispersed. The weight ratio of the conductive oxide fine particles (ITO fine particles) to the binder component (the resin binder+the curing agent) was 80:20. The mole ratio of NCO (isocyanate groups)/OH (hydroxyl groups) was 0.5.

Before the production of a flexible transparent conductive film, a base film (PET, thickness: 16 μm) lined with a supporting film (PET, thickness: 100 μm) with a heat-resistant silicone weak adhesive layer interposed therebetween was firstly subjected to thermal shrinkage treatment (with no tension at 150° C. for 5 minutes). The base film lined with the supporting film was subjected to corona discharging treatment. On the treated surface was then formed an amorphous ITO film (first transparent conductive layer, film thickness: about 0.02 μm) by sputtering.

Next, the coating liquid (liquid D) for forming the transparent conductive layer was applied on the sputtered ITO film (first transparent conductive layer, surface resistivity=300 Ω/square, transmittance=96.4%, and haze value=0.8%) by wire bar coating (wire diameter: 0.05 mm) and was then dried at 60° C. for 10 minutes, and further heated at 120° C. for 20 minutes to cure (crosslink) the binder component thermally, thereby forming a second transparent conductive layer (film thickness: about 0.3 μm) composed of the ITO fine particles and the binder matrix on the sputtered ITO film. In this way, a flexible transparent conductive film according to Example 4 was obtained, which was composed of the supporting film (lining film)/the base film/the first transparent conductive layer formed by the vapor deposition method/the second transparent conductive layer formed by the coating method.

The peel strength between the supporting film (lining film) and the base film in the flexible transparent conductive film was about 4 g/cm. The peel strength was the 180° peel strength (the base film was peeled at a tensile speed of 300 mm/min in the 180° direction). This flexible transparent conductive film had a dimension change ratio (shrinkage ratio) of about 0.05% when heated.

The laminated transparent conductive layers (the first transparent conductive layer formed by the vapor deposition method and the second transparent conductive layer formed by the coating method) had film properties of 95.9% in visible ray transmittance, 2.2% in haze value, and about 300 Ω/square in surface resistivity. The surface resistivity was measured after one hour from the formation of the transparent conductive layers in order to avoid the effect of the heat treatment (thermal curing) of the binder component. The visible ray transmittance and the haze value of the transparent conductive layers were values of only the transparent conductive layers, and were respectively calculated from calculation formulas 3 and 4 described below.

The visible ray transmittance (%) of the transparent conductive layers=[(the total transmittance of the combination of the transparent conductive layers and the base film lined with the supporting film)/the transmittance of only the base film lined with the supporting film]×100 [Calculation formula 3]

The haze value (%) of the transparent conductive layers=(the total haze value of the combination of the transparent conductive layers and the base film lined with the supporting film)−(the haze value of only the base film lined with the supporting film) [Calculation formula 4]

The adhesive strength between the first and second transparent conductive layers in the flexible transparent conductive film composed of the supporting film (lining film) /the base film/the first transparent conductive layer/the second transparent conductive layer was evaluated in a tape peeling test (crosscut test) according to JIS K5600-5-6. As a result, a good result of 25/25 (the number of pieces not peeled/the number of all the pieces [5×5=25]) was obtained. In the tape peeling test (crosscut test), the base film and the first transparent conductive layer also adhered strongly to each other, so that no peeling was observed therebetween which is similar to the interface between the first and second transparent conductive layers.

Incidentally, in the tape peeling test (crosscut test), the thickness of the base film was as thin as 16 μm. Thus, when the flexible transparent conductive film was crosscut as it was, the base film together with the transparent conductive layers would be cut. Therefore, the base film on which the transparent conductive layers were formed was once peeled from the supporting film (lining film), and then adhered onto a PET film of 100 μm thickness with an epoxy adhesive. Thereafter, the evaluation was carried out.

Next, the flexible transparent conductive film was used in a similar manner as Example 1, and produced a flexible functional element. Finally, the supporting film (lining film) was peeled off to obtain a flexible functional element (electronic paper) (thickness: about 91 μm) according to Example 4, which was composed of the base film (thickness: about 16 μm)/the first transparent conductive layer (thickness: about 0.02 μm)/the second transparent conductive layer (thickness: about 0.3 μm)/the display layer (thickness: 40 μm)/the carbon conductive layer (thickness: about 10 μm)/the PET film (thickness: 25 μm).

In order to keep the reliability, a gas barrier film (GX film, manufactured by Toppan Printing Co., Ltd. (thickness: about 13 μm)) was adhered to the flexible functional element on a side of the flexible transparent conductive film. The other side opposite thereto was also subjected to moisture-proof laminating treatment.

In the process for producing the flexible functional element, the supporting film (lining film) having the weak adhesive layer was able to be easily peeled off at the interface between the weak adhesive layer and the base film. The peel strength between the supporting film and the base film was about 4 g/cm. A direct-current voltage of 10 V was applied across the voltage-applying lead lines of the flexible functional element (electronic paper) and the polarity thereof was changed repeatedly. As a result, repeated display of white and black was observed.

### Example 5

34 g of granular ITO fine particles (trade name: SUFP-HX, manufactured by Sumitomo Metal Mining Co., Ltd.) having an average particle diameter of 0.03 μm were mixed with 24 g of methyl isobutyl ketone (MIBK) and 36 g of cyclohexanone as solvents, and the mixture was subjected to dispersing treatment. Thereafter, thereto were added 5.7 g of a urethane acrylate ultraviolet curable resin binder containing hydroxyl groups, 0.3 g of a photoinitiator (IRGACURE 184) and a trace amount of a silane coupling agent. The components were sufficiently stirred to obtain a coating liquid (liquid E) for forming a transparent conductive layer in which ITO fine particles having an average dispersion particle diameter of 120 nm were dispersed. The weight ratio of the conductive oxide fine particles (ITO fine particles) to the binder component (the resin binder+the photoinitiator) was 85:15.

A base film (PET, thickness: 6 μm) lined with a supporting film (PET, thickness: 75 μm) with a heat-resistant silicone weak adhesive layer interposed therebetween was firstly subjected to corona discharge treatment. Thereafter, the coating liquid (liquid E) for forming the transparent conductive layer was applied on the treated surface by wire bar coating (wire diameter: 0.10 mm) and then dried at 60° C. for 1 minute. Thereafter, the transparent conductive layer together with the base film lined with the supporting film were entirely subjected to rolling treatment (linear pressure: 200 kgf/cm=196 N/mm, and nip width: 0.9 mm) with metallic rolls having a diameter of 100 mm and hard chromium plated, and further the binder component was cured (under nitrogen atmosphere at 100 mW/cm² for 2 seconds) through a high-pressure mercury lamp to form a second transparent conductive layer (film thickness: about 0.5 μm) composed of the ITO fine particles filled densely and the binder matrix.

Next, an ITO film (first transparent conductive layer, film thickness: about 0.03 μm) was formed on this second transparent conductive layer (surface resistivity=1000 Ω/square, transmittance=96.5%, and haze value=1.9%) by sputtering. Furthermore, the transparent conductive layers together with the base film lined with the supporting film were entirely subjected to thermal shrinkage treatment (with no tension at 150° C. for 20 minutes) to obtain a flexible transparent conductive film according to Example 5, which was composed of the supporting film (lining film)/the base film/the second transparent conductive layer formed by the coating method/the first transparent conductive layer formed by the vapor deposition method.

The surface resistivity of the second transparent conductive layer tends to temporarily decrease its value immediately after the curing by the influence of irradiation with ultraviolet rays when the binder is cured, accordingly the value was measured after one day from the formation of the transparent conductive layers. The sputtered ITO film was not an amorphous ITO film and was mostly a crystalline ITO film.

The peel strength between the supporting film (lining film) and the base film in the flexible transparent conductive film was about 5 g/cm. This flexible transparent conductive film had a dimension change ratio (shrinkage ratio) of about 0.03% when heated.

The laminated transparent conductive layers (the second transparent conductive layer formed by the coating method and the first transparent conductive layer formed by the vapor deposition method) had film properties of 91.5% in visible ray transmittance, 2.5% in haze value, and about 70 Ω/square in surface resistivity. The visible ray transmittance and the haze value of the transparent conductive layers were values of only the transparent conductive layers, and were respectively calculated from the above-described calculation formulas 3 and 4.

The adhesive strength between the first and second transparent conductive layers in the flexible transparent conductive film composed of the supporting film (lining film)/the base film/the second transparent conductive layer/the first transparent conductive layer was evaluated in a tape peeling test (crosscut test) according to JIS K5600-5-6. As a result, a good result of 25/25 (the number of pieces not peeled/the number of all the pieces [5×5=25]) was obtained. In the tape peeling test (crosscut test), the base film and the second transparent conductive layer also adhered strongly to each other, so that no peeling was observed therebetween which is similar to the interface between the first and second transparent conductive layers.

Incidentally, in the tape peeling test (crosscut test), the thickness of the base film was as thin as 6 μm. Thus, when the flexible transparent conductive film was crosscut as it was, the base film together with the transparent conductive layers would be cut. Therefore, the base film on which the transparent conductive layers were formed was once peeled from the supporting film (lining film), and then adhered onto a PET film of 100 μm thickness with an epoxy adhesive. Thereafter the evaluation was carried out.

Next, the flexible transparent conductive film was used in a similar manner as Example 1, and produced a flexible functional element. Finally, the supporting film (lining film) was peeled off to obtain a flexible functional element (electronic paper) (thickness: about 82 μm) according to Example 5, which was composed of the base film (thickness: about 6 μm) /the second transparent conductive layer (thickness: about 0.5 μm)/the first transparent conductive layer (thickness: about 0.03 μm)/the display layer (thickness: 40 μm)/the carbon conductive layer (thickness: about 10 μm)/the PET film (thickness: 25 μm).

In order to keep the reliability, a gas barrier film (GX film, manufactured by Toppan Printing Co., Ltd. (thickness: about 13 μm)) was adhered to the flexible functional element on a side of the flexible transparent conductive film. The other side opposite thereto was also subjected to moisture-proof laminating treatment.

In the process for producing the flexible functional element, the supporting film (lining film) having the weak adhesive layer was able to be easily peeled off at the interface between the weak adhesive layer and the base film. The peel strength between the supporting film and the base film was about 5 g/cm. A direct-current voltage of 10 V was applied across the voltage-applying lead lines of the flexible functional element (electronic paper) and the polarity thereof was changed repeatedly. As a result, repeated display of white and black was observed.

### Comparative Example 1

A low heat shrinkage type PET film (thickness: about 100 μm, transmittance=89.8%, and haze value=1.9%) as a base film was subjected to corona discharge treatment, and then the same coating liquid (liquid A) for forming the transparent conductive layer as in Example 1 was applied on the treated surface by wire bar coating (wire diameter: 0.10 mm) and dried at 60° C. for 1 minute. Thereafter, the workpiece was subjected to rolling treatment (linear pressure: 200 kgf/cm=196 N/mm, and nip width: 0.9 mm) with metallic rolls having a diameter of 100 mm and hard chromium plated, and further the binder component was cured (under nitrogen atmosphere at 100 mW/cm² for 2 seconds) through a high-pressure mercury lamp to form a transparent conductive layer (film thickness: about 0.5 μm) composed of the ITO fine particles filled densely and the binder matrix on the transparent coating layer. In this way, a flexible transparent conductive film according to Comparative Example 1 was obtained which was composed of the base film, and the second transparent conductive layer formed by the coating method. This flexible transparent conductive film had a dimension change ratio (shrinkage ratio) of about 0.3% when heated.

The second transparent conductive layer has film properties of 95.5% in visible ray transmittance, 2.0% in haze value, and 1500 Ω/square in surface resistivity. The visible ray transmittance and the haze value of the transparent conductive layer were values of only the transparent conductive layer, and were respectively calculated from the calculation formulas 1 and 2. The surface resistivity tends to temporarily decrease its value immediately after the curing by the influence of irradiation with ultraviolet rays when the binder is cured, accordingly the value was measured after one day from the formation of the transparent conductive layers.

The adhesive strength between the base film and the second transparent conductive layer in the flexible transparent conductive film composed of the base film and the second transparent conductive layer was evaluated in a tape peeling test (crosscut test) according to JIS K5600-5-6. As a result, a good result of 25/25 (the number of pieces not peeled/the number of all the pieces [5×5=25]) was obtained.

In a manner similar to Example 1 other than using the flexible transparent conductive film having the transparent conductive layer, a silver conductive paste was applied to form a voltage-applying Ag lead line at each end of the transparent conductive layer and the carbon conductive layer, which are adhered to each other with the display layer interposed therebetween. In this way, a flexible functional element (electronic paper) (thickness: about 176 μm) according to Comparative Example 1 was obtained, which was composed of the base film (thickness: about 100 μm)/the transparent conductive layer (thickness: about 0.5 μm)/the display layer (thickness: 40 μm)/the carbon conductive layer (thickness: about 10 μm)/the PET film (thickness: 25 μm).

In order to keep the reliability, a gas barrier film (GX film, manufactured by Toppan Printing Co., Ltd. (thickness: about 13 μm)) was adhered to the flexible functional element on a side of the flexible transparent conductive film. The other side opposite thereto was also subjected to moisture-proof laminating treatment.

A direct-current voltage of 10 V was applied across the voltage-applying lead lines of the flexible functional element (electronic paper) and the polarity thereof was changed repeatedly. As a result, repeated display of white and black was observed. However, when the silver conductive paste was used to form the voltage-applying Ag lead line at the end of the transparent conductive layer adhered via the interposed display layer, the display layer was intensely rubbed back and forth 50 times with a cotton swab impregnated with acetone so as to remove the display layer, and exposed the surface of the transparent conductive layer. Consequently, many scratches reaching the base film were observed in the transparent conductive layer, and a region where the conductivity was completely lost was also observed.

### Comparative Example 2

A low heat shrinkage type PET film (thickness: about 100 μm, transmittance=89.8%, and haze value=1.9%) as a base film was subjected to corona discharge treatment, and then an amorphous ITO film (first transparent conductive layer, film thickness: about 0.02 μm) was formed on the treated surface by sputtering, so as to obtain a flexible transparent conductive film according to Comparative Example 2, which was composed of the base film/the first transparent conductive layer formed by the vapor deposition method. This flexible transparent conductive film had a dimension change ratio (shrinkage ratio) of about 0.3% when heated.

The first transparent conductive layer has film properties of 96.5% in the visible ray transmittance, 0.8% in haze value, and 300 Ω/square in surface resistivity. The visible ray transmittance and the haze value of the transparent conductive layers were values of only the transparent conductive layer, and were respectively calculated from the calculation formulas 1 and 2. The adhesive strength between the base film and the first transparent conductive layer in the flexible transparent conductive film composed of the base film and the first transparent conductive layer was evaluated in a tape peeling test (crosscut test) according to JIS K5600-5-6. As a result, a good result of 25/25 (the number of pieces not peeled/the number of all the pieces [5×5=25]) was obtained.

In a manner similar to Example 1 other than using the flexible transparent conductive film having the transparent conductive layer, a silver conductive paste was applied to form a voltage-applying Ag lead line at each end of the sputtered ITO layer (the first transparent conductive layer) and the carbon conductive layer, which are adhered to each other with the display layer interposed therebetween. In this way, a flexible functional element (electronic paper) (thickness: about 175 μm) according to Comparative Example 2 was obtained, which was composed of the base film (thickness: about 100 μm)/the sputtered ITO layer (thickness: about 0.02 μm)/the display layer (thickness: 40 μm)/the carbon conductive layer (thickness: about 10 μm)/the PET film (thickness: 25 μm)

In order to keep the reliability, a gas barrier film (GX film, manufactured by Toppan Printing Co., Ltd. (thickness: about 13 μm)) was adhered to the flexible functional element on a side of the flexible transparent conductive film. The other side opposite thereto was also subjected to moisture-proof laminating treatment. A direct-current voltage of 10 V was applied across the voltage-applying lead lines of the flexible functional element (electronic paper) and the polarity thereof was changed repeatedly. As a result, repeated display of white and black was observed.

### Comparative Example 3

On the base film (PET, thickness: 16 μm) lined with the supporting film (PET thickness: 100 μm) which is similar to Example 4, an amorphous ITO film (first transparent conductive layer, film thickness: about 0.02 μm) was formed by sputtering so as to obtain a flexible transparent conductive film according to Comparative Example 3, which was composed of the supporting film (lining film)/the base film/the first transparent conductive layer formed by the vapor deposition method. The peel strength between the supporting film (lining film) and the base film in the flexible transparent conductive film was about 4 g/cm. This flexible transparent conductive film had a dimension change ratio (shrinkage ratio) of about 0.05% when heated.

The first transparent conductive layer has film properties of 96.4% in visible ray transmittance, 0.8% in haze value, and 300 Ω/square in surface resistivity. The visible ray transmittance and the haze value of the transparent conductive layer were values of only the transparent conductive layer, and were respectively calculated from the calculation expressions 3 and 4.

The adhesive strength between the base film and the first transparent conductive layer in the flexible transparent conductive film composed of the supporting film (lining film)/the base film/the first transparent conductive layer was evaluated in a tape peeling test (crosscut test) according to JIS K5600-5-6. As a result, a good result of 25/25 (the number of pieces not peeled/the number of all the pieces [5×5=25]) was obtained. Incidentally, in the tape peeling test (crosscut test), the thickness of the base film was as thin as 16 μm. Thus, when the flexible transparent conductive film was crosscut as it was, the base film together with the transparent conductive layer would be cut. Therefore, the base film on which the transparent conductive layer was formed was once peeled from the supporting film (lining film), and then adhered onto a PET film of 100 μm thickness with an epoxy adhesive. Thereafter, the evaluation was carried out.

Next, the flexible transparent conductive film was used in a similar manner as Example 1, and produced a flexible functional element. Finally, the supporting film (lining film) was peeled off to obtain a flexible functional element (electronic paper) (thickness: about 91 μm) according to Comparative Example 3, which was composed of the base film (thickness: about 16 μm) /the first transparent conductive layer (thickness: about 0.02 μm)/the display layer (thickness: 40 μm)/the carbon conductive layer (thickness: about 10 μm)/the PET film (thickness: 25 μm).

In order to keep the reliability, a gas barrier film (GX film, manufactured by Toppan Printing Co., Ltd. (thickness: about 13 μm)) was adhered to the flexible functional element on a side of the flexible transparent conductive film. The other side opposite thereto was also subjected to moisture-proof laminating treatment.

In the process for producing the flexible functional element, the supporting film (lining film) having the weak adhesive layer was able to be easily peeled off at the interface between the weak adhesive layer and the base film. The peel strength between the supporting film and the base film was about 4 g/cm. A direct-current voltage of 10 V was applied across the voltage-applying lead line of the flexible functional element (electronic paper) and the polarity thereof was changed repeatedly. As a result, repeated display of white and black was observed.

Next, the flexible transparent conductive films and the flexible functional elements of the above examples and the comparative examples were evaluated from a viewpoint of flexibility. Furthermore, the flexible transparent conductive film of the above examples and the comparative examples were evaluated from viewpoints of solvent and scratch resistance, and stability of conductivity (durability).

“Flexibility Evaluations (1) of the Flexible Transparent Conductive Films”

Each of the flexible transparent conductive films of Examples 1 to 3 and Comparative Examples 1 and 2 was wound one time around a rod having a diameter of 8 mm with a side of the transparent conductive layer facing inside, and wound one time therearound with this side facing outside, and thereafter, the surface resistivity was measured. In each of the transparent conductive films of Examples 1 to 3, the surface resistivity was raised from an initial value of about 300 Ω/square to about 400 Ω/square. However, no change was observed in the external appearance. In the transparent conductive film of Comparative Example 1, a change in the resistance value was hardly observed. However, the initial surface resistivity was as high as 1500 Ω/square. In Comparative Example 2, the sputtered ITO layer was cracked so that the surface resistivity in the winding direction was largely raised up to several tens of kiloohms per square.

In each of the flexible transparent conductive films of Examples 4 and 5, and Comparative Example 3, the supporting film (lining film) was removed by peeling off, and then wound one time around a rod having a diameter of 2 mm with a side of the transparent conductive layer facing inside, and wound one time therearound with this side facing outside, and thereafter, the surface resistivity was measured. In the transparent conductive film of Example 4, the surface resistivity was slightly raised from an initial value of about 300 Ω/square to about 310 Ω/square. In the transparent conductive film of Example 5 also, the surface resistivity was slightly raised from an initial value of about 70 Ω/square to about 80 Ω/square. However, no remarkable change was observed in the external appearance. In Comparative Example 3, the sputtered ITO layer was cracked so that the surface resistivity in the winding direction was largely raised from about 300 Ω/square to about 1000 Ω/square.

In the flexibility evaluations of the flexible transparent conductive films, each of the sputtered ITO layers (first transparent conductive layers) of Examples 1 to 4 and Comparative Examples 1 to 3 was inspected from a viewpoint of degree of cracking. As a result, in each of the examples, even though the sputtered ITO layer was slightly cracked, it was confirmed that the generation of the crack(s) had been greatly restrained by the second transparent conductive layer, which strongly adhered to the sputtered ITO layer, as compared with the comparative examples.

It is also confirmed that, in Examples 1 to 5, even when the sputtered ITO layer was cracked, a rise in the resistance value of the transparent conductive layer was slight, and deterioration in the conductivity of the transparent conductive layers was restrained by the second transparent conductive layer which strongly adhered to the sputtered ITO layer.

“Flexibility Evaluations (2) of the Flexible Transparent Conductive Films”

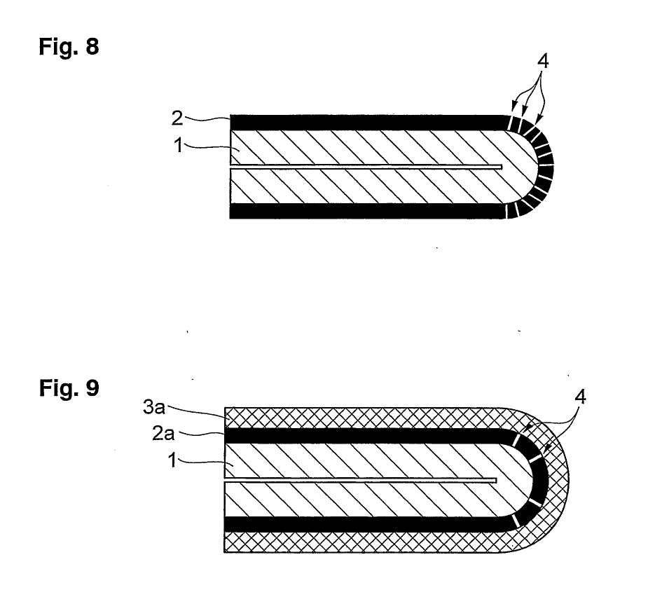

From each of the flexible transparent conductive films of Example 4 and Comparative Example 3, the supporting film (lining film) was removed by peeling off. Thereafter, as illustrated in FIG. 7, a silver conductive paste was applied to form parallel, electrodes 6 on the transparent conductive layer surface 5a of each flexible transparent conductive film 5 to produce test samples for flexibility-evaluations. Next, the resistance value across the parallel electrodes of the test sample was measured for each of Example 4 and Comparative Example 3. As illustrated in FIGS. 8 and 9, each sample was completely twice-folded with a side having the transparent conductive layer facing outside. Thereafter, each sample was unfolded into the original state, and then the resistance value across the parallel electrodes was again measured. It is to be noted that the testing condition was very severe for the samples because each sample was folded in such a manner as to induce a tensile stress in the sputtered ITO layer by making a curvature radius zero so that a crack would be easily generated therein (i.e., in such a manner that each sample was folded with its side having the transparent conductive layer facing outside). Specifically, each test sample was twice-folded on its folding line 7 shown in FIG. 7, and further the folded sample was pressed from thereabove along the folding line with fingers.

In the test sample of Example 4, the resistance value was deteriorated from an initial value of about 300Ω to about 950Ω, however, the conductivity of the transparent conductive layer was not lost. Additionally, even though a trace of the fold remained in the base film itself, no remarkable change other than the trace was observed in the external appearance. On the other hand, in the test sample of Comparative Example 3, many cracks were generated in the fold region of the sputtered ITO layer, which increased the resistance value from an initial value of about 300Ω to 10 MΩ or more so that the conductivity of the fold region of the transparent conductive layer was completely lost.

In the flexibility evaluation of Example 4 and Comparative Example 3, each of the sputtered ITO layers (first transparent conductive layers) was inspected from a viewpoint of degree of cracking around the fold region. As a result, in Example 4, even though the sputtered ITO layer was cracked, it was confirmed that the generation of the cracks was greatly restrained by the second transparent conductive layer, which strongly adhered to the sputtered ITO layer, as compared with Comparative Example 3.

Further, in Example 4, even though the sputtered ITO layer was cracked, the conductivity of the transparent conductive layers was not lost. It was also confirmed that deterioration in the conductivity of the transparent conductive layers was restrained by the second transparent conductive layer which strongly adhered to the sputtered ITO layer.

“Flexibility Evaluations of the Flexible Functional Elements (Electronic Papers)”

Each of the flexible functional elements (electronic papers) of Examples 1 to 3 and Comparative Examples 1 and 2 was wound one time around a rod having a diameter of 8 mm with the display surface facing inside, and wound one time therearound with the display surface facing outside. Thereafter, a direct-current voltage of 10 V was applied across the voltage-applying lead lines. The polarity thereof was changed repeatedly so as to repeat display of white and black, and the display state thereof was observed. In each of Examples 1 to 3 and Comparative Example 1, the display state was not changed. In Comparative Example 2, the sputtered ITO layer was cracked so that displaying was performed only partially.

Each of the flexible functional elements (electronic papers) of Example 4 and Comparative Example 3 was wound one time around a rod having a diameter of 4 mm with the display surface facing inside, and wound one time therearound with the display surface facing outside. Thereafter, a direct-current voltage of 10 V was applied across the voltage-applying lead lines. The polarity thereof was changed repeatedly so as to repeat display of white and black, and the display state thereof was observed. In Example 4, the display state was not changed. In Comparative Example 3, the sputtered ITO layer was cracked so that displaying was performed only partially.

The flexibility evaluation of the flexible functional elements had no intention to examine the long-term reliability of the functional elements. Therefore, for the sake of convenience, the evaluations were carried out without having the gas barrier film nor applying the moisture-proof laminating treatment to be used for keeping the reliability of the functional elements.

“Solvent and Scratch Resistance Evaluations of the Flexible Transparent Conductive Films”

The transparent conductive layer surface of each of the flexible transparent conductive films of the Examples and the Comparative Examples was rubbed back and forth 10 times with a cotton swab impregnated with acetone. A change in the external appearance was then observed. As a result, the appearance was not changed at all. The resistance value of the film and optical property thereof were not largely changed, either.

The transparent conductive layer surface of each of the flexible transparent conductive films of the Examples and the Comparative Examples was intensely rubbed back and forth 50 times with a cotton swab impregnated with acetone. As a result, even though a scratch was observed in some of the second transparent conductive layers of the flexible transparent conductive films among the Examples, no region was observed where the conductivity of the transparent conductive layer was completely lost. Similarly, no region was observed where the conductivity of the transparent conductive layer was completely lost in the flexible transparent conductive films of Comparative Examples 2 and 3, which had only the sputtered ITO layer. On the other hand, a scratch reaching the base film was observed in the flexible transparent conductive film of Comparative Example 1, which had only the second transparent conductive layer formed by the coating method. Further, a region where the conductivity was completely lost was also observed.

“Stability of Conductivity (Durability) Evaluations of the Flexible Transparent Conductive Films”

Each of the flexible transparent conductive films of the examples was allowed to stand still in an environment of 25° C. and 50 to 60% relative humidity for 3 months. The surface resistivity of the transparent conductive layers, the external appearance of the film, and optical property thereof were measured and observed. As a result, no change was observed. The flexible transparent conductive films of Comparative Examples 2 and 3 having only the sputtered ITO layer were evaluated in the similar manner, and no change were observed. On the other hand, the flexible transparent conductive film of Comparative Example 1 having only the second transparent conductive layer formed by the coating method was allowed to stand still in the same condition as above. As a result, the resistance was raised to about 4 times the initial resistance value.

1-10. (canceled)

11. A flexible transparent conductive film comprising: a base film; a first transparent conductive layer formed by a physical or chemical vapor deposition method; and a second transparent conductive layer formed by a coating method, these layers being laminated in the described order or in order reversed to the described order on the base film,
wherein the first transparent conductive layer mainly includes a conductive oxide, the second transparent conductive layer mainly includes conductive oxide fine particles and a binder matrix, and the first transparent conductive layer and the second transparent conductive layer adhere to each other so as to restrain generation of a crack in the first transparent conductive layer, or to restrain a deterioration in conductivity when the crack has been generated.

12. The flexible transparent conductive film according to claim 11, wherein the second transparent conductive layer is subjected to compression treatment.

13. The flexible transparent conductive film according to claim 11, wherein the physical or chemical vapor deposition method is sputtering, ion plating, vacuum evaporation, thermal CVD, optical CVD, Cat-CVD, or MOCVD.

14. The flexible transparent conductive film according to claim 12, wherein the physical or chemical vapor deposition method is sputtering, ion plating, vacuum evaporation, thermal CVD, optical CVD, Cat-CVD, or MOCVD.

15. The flexible transparent conductive film according to claim 11, wherein the conductive oxide and the conductive oxide fine particles mainly includes one or more components selected from the group consisting of indium oxide, tin oxide, and zinc oxide.

16. The flexible transparent conductive film according to claim 12, wherein the conductive oxide and the conductive oxide fine particles mainly includes one or more components selected from the group consisting of indium oxide, tin oxide, and zinc oxide.

17. The flexible transparent conductive film according to claim 11, wherein the oxide included in the conductive oxide and the conductive oxide fine particles is indium tin oxide.

18. The flexible transparent conductive film according to claim 12, wherein the oxide included in the conductive oxide and the conductive oxide fine particles is indium tin oxide.

19. The flexible transparent conductive film according to claim 11, wherein the binder matrix in crosslinked, and has organic-solvent resistance.

20. The flexible transparent conductive film according to claim 12, wherein the binder matrix in crosslinked, and has organic-solvent resistance.

21. The flexible transparent conductive film according to claim 12, wherein the compression treatment is performed by rolling treatment using rolls.

22. The flexible transparent conductive film according to claim 11, wherein the base film has a thickness of 3 to 50 μm, and a supporting film is adhered onto a surface of the base film, the supporting film has a capability of being peeled off at an interface between the supporting film and the base film.

23. The flexible transparent conductive film according to claim 12, wherein the base film has a thickness of 3 to 50 μm, and a supporting film is adhered onto a surface of the base film, the supporting film has a capability of being peeled off at an interface between the supporting film and the base film.

24. A flexible functional element having a functional element formed on the flexible transparent conductive film according to claim 11, the functional element being a liquid crystal display element, an organic electroluminescence element, an inorganic dispersion-type electroluminescence element, an electronic paper element, a solar cell, or a touch panel.

25. A flexible functional element having a functional element formed on the flexible transparent conductive film according to claim 12, the functional element being a liquid crystal display element, an organic electroluminescence element, an inorganic dispersion-type electroluminescence element, an electronic paper element, a solar cell, or a touch panel.

26. A flexible functional element having a functional element formed on the flexible transparent conductive film according to claim 13, the functional element being a liquid crystal display element, an organic electroluminescence element, an inorganic dispersion-type electroluminescence element, an electronic paper element, a solar cell, or a touch panel.

27. A flexible functional element having a functional element formed on the flexible transparent conductive film according to claim 14, the functional element being a liquid crystal display element, an organic electroluminescence element, an inorganic dispersion-type electroluminescence element, an electronic paper element, a solar cell, or a touch panel.

28. A flexible functional element having a functional element formed on the flexible transparent conductive film according to claim 15, the functional element being a liquid crystal display element, an organic electroluminescence element, an inorganic dispersion-type electroluminescence element, an electronic paper element, a solar cell, or a touch panel.

29. A flexible functional element having a functional element formed on the flexible transparent conductive film according to claim 16, the functional element being a liquid crystal display element, an organic electroluminescence element, an inorganic dispersion-type electroluminescence element, an electronic paper element, a solar cell, or a touch panel.

30. A flexible functional element having a functional element formed on the flexible transparent conductive film according to claim 17, the functional element being a liquid crystal display element, an organic electroluminescence element, an inorganic dispersion-type electroluminescence element, an electronic paper element, a solar cell, or a touch panel.

31. The flexible functional element having a functional element formed on the flexible transparent conductive film according to claim 22, the functional element being a liquid crystal display element, an organic electroluminescence element, an inorganic dispersion-type electroluminescence element, an electronic paper element, a solar cell, or a touch panel, wherein the supporting film has been peeled off at the interface between the supporting film and the base film.

32. The flexible functional element having a functional element formed on the flexible transparent conductive film according to claim 23, the functional element being a liquid crystal display element, an organic electroluminescence element, an inorganic dispersion-type electroluminescence element, an electronic paper element, a solar cell, or a touch panel, wherein the supporting film has been peeled off at the interface between the supporting film and the base film.
